(19) United States
(12) Patent Application Publication
(10) Pub. No.: US 2026/0033177 A1
(43) Pub. Date: Jan. 29, 2026

(54) DISPLAY SUBSTRATE AND DISPLAY DEVICE

(71) Applicants: Chengdu BOE Optoelectronics Technology Co., Ltd., Chengdu (Sichuan) (CN); BOE TECHNOLOGY GROUP CO., LTD., Beijing (CN)

(72) Inventors: Mengqi WANG, Beijing (CN); Ziyang YU, Beijing (CN); Zhiliang JIANG, Beijing (CN); Ming HU, Beijing (CN); Fei CHEN, Beijing (CN)

(73) Assignees: Chengdu BOE Optoelectronics Technology Co., Ltd., Chengdu (Sichuan) (CN); BOE TECHNOLOGY GROUP CO., LTD., Beijing (CN)

(21) Appl. No.: 18/995,288

(22) PCT Filed: Feb. 19, 2024
(86) PCT No.: PCT/CN2024/077571

§ 371 Date: Jan. 16, 2025

(30) Foreign Application Priority Data
Mar. 21, 2023 (CN) 202310280616.8

(51) Int. Cl. H10K 59/131; H10D 86/40; H10D 86/60; H10K 59/121

(52) U.S. Cl. CPC H10K 59/131; H10K 59/1213; H10D 86/441; H10D 86/60

(57) ABSTRACT

A display substrate and a display device are provided, the display substrate includes: a display region and a peripheral region; sub pixels arranged in the display region, each column of the sub pixels being connected with a data line; the fanout region including a connection region adjacent to the display region, a part of data lines being directly connected with connection pads located in the connection region, and other part of the data lines being connected with connection pads located in the connection region through data connection lines; in which the sub pixels include columns of first color sub pixels and columns of second color sub pixels, the connection pads include first connection pads and second connection pads, the first connection pads are electrically connected with the columns of first color sub pixels and the second connection pads are electrically connected with the columns of second color sub pixels.

This application claims the priority and benefits of the Chinese Patent Applications No. 202310280616.8, which was filed on Mar. 21, 2023, the disclosure of which is incorporated herein by reference in its entirety as part of the present application.

### TECHNICAL FIELD

Embodiments of the present disclosure relate to a display substrate and a display device.

### BACKGROUND

With the continuous development of display technology, the demand of consumers for narrow frame design of display devices is getting higher and higher. Therefore, how to further reduce the frame width of display devices has become the focus and hot spot of researchers in the display field. Compared with traditional liquid crystal display devices, organic light emitting diode (OLED) display products, which are commonly used in narrow frame design, have the advantages of self-luminescence, wide color gamut, high contrast and lightness, which makes them widely used in electronic devices such as mobile phones and tablet computers.

Generally, the display region of a display substrate includes a plurality of signal lines for driving the pixel structure in the display substrate to perform light emitting display, and these signal lines need to be driven by a driving circuit or a driving chip electrically connected with them, the driving circuit or the driving chip is usually arranged in the peripheral region of the display substrate. Therefore, it is needed to lead out various signal lines in the display region, such as data lines, to the fanout region, and then connect the various signal lines to the peripheral region that does not perform the display function but includes an integrated circuit through the fanout region, the peripheral region includes a lead wire region and a bonding region. The lead wire region includes a plurality of lead wires, and the bonding region is used for bonding with an external driving circuit or a driving chip. In this case, the plurality of lead wires can be electrically connected with a plurality of signal lines and extend to the bonding region, so that the pixel structure is bound with the external driving circuit or driving chip.

### SUMMARY

At least one embodiment of the present disclosure provides a display substrate and a display device. A data line jumper design is performed on the display substrate at a connection region of a fanout region adjacent to a display region (AA), that is, an arrangement order of sub pixels connected with data lines and data connection lines at a position of the display region close to the fanout region is different from an arrangement order of sub pixels connected with a plurality of first signal transmission lines and a plurality of second signal transmission lines at a position of the fanout region away from the display region, so that a plurality of first signal transmission lines or a plurality of second signal transmission lines connected with sub pixels of the same color are adjusted to be located in the same film layer, so as to avoid different parasitic capacitances in the case that the plurality of first signal transmission lines or the plurality of second signal transmission lines which are connected with sub pixels of the same color are located in different film layers, and further avoid the problem that different loads of the plurality of first signal transmission lines or the plurality of second signal transmission lines connected with sub pixels of the same color cause different data signal writing amounts.

At least one embodiment of the present disclosure provides a display substrate, which includes: a base substrate, comprising a display region and a peripheral region surrounding the display region, the peripheral region comprising a fanout region adjacent to the display region and a pad region at a side of the fanout region away from the display region; and a plurality of sub pixels arranged in a matrix and arranged in the display region, each column of the plurality of sub pixels being connected with a data line; the fanout region comprising a connection region adjacent to the display region, a part of data lines being directly connected with connection pads located in the connection region, and other part of the data lines being connected with connection pads located in the connection region through data connection lines; in which the plurality of sub pixels comprise a plurality of columns of first color sub pixels and a plurality of columns of second color sub pixels, and the connection pads comprise a plurality of first connection pads and a plurality of second connection pads, the plurality of first connection pads are electrically connected with the plurality of columns of first color sub pixels and the plurality of second connection pads are electrically connected with the plurality of columns of second color sub pixels; a plurality of first signal transmission lines and a plurality of second signal transmission lines are arranged at intervals in positions of the fanout region close to the pad region, the plurality of first signal transmission lines are arranged in a first metal layer, and the plurality of second signal transmission lines are arranged in a second metal layer which is different from the first metal layer; the plurality of first signal transmission lines and the plurality of first connection pads are electrically connected in one-to-one correspondence, and the plurality of second signal transmission lines and the plurality of second connection pads are electrically connected in one-to-one correspondence; in which two adjacent data connection lines of the data connection lines and at least two data lines of the data lines which are located between the two adjacent data connection lines are taken as a data line group, connection pads connected with the at least two data lines in one data line group at least comprise one first connection pad and one second connection pad, in at least one data line group, an orthographic projection of a data line connected with the second connection pad on the base substrate and an orthographic projection of a first signal transmission line connected with the first connection pad on the base substrate have an overlapping part in the fanout region; or, connection pads respectively connected with the at least two data lines and the two adjacent data connection lines in the data line group comprise a first connection pad and a second connection pad, and in at least one data line group, one data connection line of the two adjacent data connection lines is electrically connected with the first connection pad or the second connection pad through a connection electrode, and an orthographic projection of the connection electrode on the base substrate and an orthographic projection of a data line, which is adjacent to the data connection line connected with the connection electrode, on the base substrate has an overlapping part in the fanout region.

For example, in the display substrate provided by at least one embodiment of the present disclosure, the data lines and the data connection lines are arranged in a third conductive layer, and connection pads connected with two adjacent data lines in one data line group are the first connection pad and the second connection pad respectively; a first data line located in an odd-numbered column among the two adjacent data lines in one data line group crosses a first signal transmission line connected with a second data line located in an even-numbered column and being adjacent to the first data line; the second data line located in the even-numbered column extends to a side of a junction of the display region and the fanout region close to the first data line adjacent to the second data line, so as to be electrically connected with a corresponding first signal transmission line of the plurality of first signal transmission lines.

For example, in the display substrate provided by at least one embodiment of the present disclosure, the first data line located in the odd-numbered column first extends to a side close to the pad region in the fanout region, and then extends to the second data line located in the even-numbered column and being adjacent to the first data line, so as to form an L-shaped structure or an inverted L-shaped structure, and the second data line located in the even-numbered column first extends to a side close to the first data line in the fanout region, and then extends to a side close to the pad region to form an unclosed quadrilateral with the first data line.

For example, in the display substrate provided by at least one embodiment of the present disclosure, on a plane parallel to a main surface of the base substrate, the first data line and the first signal transmission line connected with the second data line cross with each other; the second data line and the second signal transmission line electrically connected with the first data line do not cross with each other.

For example, in the display substrate provided by at least one embodiment of the present disclosure, the plurality of first signal transmission lines and the plurality of second signal transmission lines are alternately arranged in sequence.

For example, in the display substrate provided by at least one embodiment of the present disclosure, a plurality of third signal transmission lines and a plurality of fourth signal transmission lines are arranged in the second direction and in the pad region, an arrangement order of the sub pixels connected with the plurality of third signal transmission lines and the plurality of fourth signal transmission lines is consistent with an arrangement order of the sub pixels connected with the data lines and the data connection lines, a part of the plurality of third signal transmission lines are in odd-numbered columns, other part of the plurality of third signal transmission lines are in even-numbered columns, a part of the plurality of fourth signal transmission lines are in odd-numbered columns, and other part of the plurality of fourth signal transmission lines are in even-numbered columns, and at least one of the plurality of third signal transmission lines and the second data line correspond to the sub pixels with a same color, and at least one of the plurality of fourth signal transmission lines and the first data line corresponds to the sub pixels with a same color.

For example, in the display substrate provided by at least one embodiment of the present disclosure, a third signal transmission line arranged in an even-numbered column is electrically connected with a corresponding first signal transmission line through a first transfer line, and a fourth signal transmission line arranged in an odd-numbered column is electrically connected with a corresponding second signal transmission line through a second transfer line, the first transfer line and the second transfer line are arranged in different layers, the first transfer line is arranged in a first conductive layer, the second transfer line is arranged in a second conductive layer, and the first conductive layer and the second conductive layer are different layers.

For example, in the display substrate provided by at least one embodiment of the present disclosure, a fourth signal transmission line arranged in an even-numbered column is electrically connected with a corresponding second signal transmission line through a fourth transfer line, and a third signal transmission line arranged in an odd-numbered column is electrically connected with a corresponding first signal transmission line through a third transfer line, and both the third transfer line and the fourth transfer line are arranged in the second conductive layer.

For example, in the display substrate provided by at least one embodiment of the present disclosure, at least one third signal transmission line arranged in the even-numbered column and one fourth signal transmission line arranged in the odd-numbered column are arranged adjacent to each other, and, on a plane parallel to a main surface of the base substrate, the first transfer line connected with the at least one third signal transmission line arranged in the even-numbered column and the second transfer line connected with the fourth signal transmission line arranged in the odd-numbered column cross with each other.

For example, in the display substrate provided by at least one embodiment of the present disclosure, the data lines and the data connection lines are arranged in a third conductive layer, at least one data connection line located in an odd-numbered column and one data line located in an even-numbered column are arranged adjacent to each other; the at least one data connection line located in the odd-numbered column crosses the data line located in the even-numbered column which is adjacent to the at least one data connection line through a first connection electrode, so as to be electrically connected with a first signal transmission line corresponding to the at least one data connection line located in the odd-numbered column, the first connection electrode is located in a second conductive layer, and the second conductive layer and the third conductive layer are different layers; the data line located in the even-numbered column is electrically connected with a corresponding second signal transmission line.

For example, in the display substrate provided by at least one embodiment of the present disclosure, the first connection electrode extends in a direction from the at least one data connection line located in the odd-numbered column to the data line located in the even-numbered column at a junction of the display region and the fanout region.

For example, in the display substrate provided by at least one embodiment of the present disclosure, the data lines and the data connection lines are arranged in a third conductive layer, at least one data line located in an odd-numbered column and one data connection line located in an even-numbered column are arranged adjacent to each other; the data connection line located in the even-numbered column crosses the data line located in the odd-numbered column through a second connection electrode, so as to be electrically connected with a second signal transmission line corresponding to the data connection line located in the even-numbered column, the second connection electrode is located in a second conductive layer, and the second conductive layer and the third conductive layer are different layers; the at least one data line located in the odd-numbered column is electrically connected with a corresponding first signal transmission line.

For example, in the display substrate provided by at least one embodiment of the present disclosure, the second connection electrode extends in a direction from the data connection line located in the even-numbered column to the at least one data line located in the odd-numbered column at a junction of the display region and the fanout region.

For example, in the display substrate provided by at least one embodiment of the present disclosure, the plurality of first signal transmission lines are located in even-numbered columns and the plurality of second signal transmission lines are located in odd-numbered columns.

For example, in the display substrate provided by at least one embodiment of the present disclosure, a plurality of third signal transmission lines and a plurality of fourth signal transmission lines are arranged at a junction of the fanout region and the pad region in the second direction, an arrangement order of the sub pixels connected with the plurality of third signal transmission lines and the plurality of fourth signal transmission lines is consistent with an arrangement order of the sub pixels connected with the data lines and the data connection lines, and a part of the plurality of third signal transmission lines is in odd-numbered columns, other part of the plurality of third signal transmission lines is in even-numbered columns, a part of the plurality of fourth signal transmission lines is in the odd-numbered columns, other part of the plurality of fourth signal transmission lines is in the even-numbered columns, and the plurality of third signal transmission lines and the first connection pads are arranged in one-to-one correspondence, and correspond to the sub pixels of a same color, and the plurality of fourth signal transmission lines and the second connection pads are arranged in one-to-one correspondence, and correspond to the sub pixels of a same color.

For example, in the display substrate provided by at least one embodiment of the present disclosure, the third signal transmission line arranged in the odd-numbered column is electrically connected with a corresponding first signal transmission line through a first transfer line, and a fourth signal transmission line arranged in the even-numbered column is electrically connected with a corresponding second signal transmission line through a second transfer line, the first transfer line is in a second conductive layer, the second transfer line is in a first conductive layer, and the first conductive layer and the second conductive layer are different layers.

For example, in the display substrate provided by at least one embodiment of the present disclosure, the third signal transmission line arranged in the even-numbered column is electrically connected with a corresponding first signal transmission line through a third transfer line, and the fourth signal transmission line arranged in the odd-numbered column is electrically connected with a corresponding second signal transmission line through a fourth transfer line, and both the third transfer line and the fourth transfer line are arranged in the second conductive layer.

For example, in the display substrate provided by at least one embodiment of the present disclosure, at least one of the third signal transmission lines arranged in the odd-numbered column and one fourth signal transmission line arranged in the even-numbered column are arranged adjacent to each other, and on a plane parallel to a main surface of the base substrate, the first transfer line connected with the at least one of the third signal transmission lines arranged in the odd-numbered column and the second transfer line connected with the fourth signal transmission line arranged in the even-numbered column cross with each other.

For example, in the display substrate provided by at least one embodiment of the present disclosure, the fanout region further comprises a semiconductor layer, a first gate layer, a second gate layer, an interlayer insulating layer, a first conductive layer, a planarization layer and a second conductive layer which are sequentially stacked; the first color sub pixels comprise a green sub pixel, and the second color sub pixels comprise a red sub pixel and a blue sub pixel; a test unit is arranged in the fanout region, and the test unit comprises a first test switching transistor connected with the red sub pixel and a second test switching transistor connected with the blue sub pixel; a source electrode of the first test switching transistor is connected with a first test signal input end, a part of the plurality of second signal transmission lines is electrically connected with a drain electrode of the first test switching transistor, and a gate electrode of the first test switching transistor is electrically connected with a first part of the first conductive layer; a source electrode of the second test switching transistor is connected with a second test signal input end, other part of the plurality of second signal transmission lines is electrically connected with a drain electrode of the second test switching transistor, and a gate electrode of the second test switching transistor is electrically connected with a second part of the first conductive layer; the first part and the second part of the first conductive layer are spaced apart from each other.

At least one embodiment of the present disclosure further provides a display device, and the display device comprises any one of the display substrates mentioned above.

### BRIEF DESCRIPTION OF DRAWINGS

In order to explain the technical solution of the embodiments of the present disclosure more clearly, the attached drawings of the embodiments of the present disclosure will be briefly introduced below. The attached drawings are only used to show some embodiments of the present disclosure, and are not limited to all embodiments of the present disclosure.

FIG. 1 is a schematic diagram of an arrangement of data signal lines in a display region and a fanout region in a display substrate;

FIG. 2 is a schematic plan view of a display substrate provided by at least one embodiment of the present disclosure;

FIG. 3 is a schematic diagram of an arrangement of data lines, data connection lines and signal transmission lines in a display region and a fanout region in a display substrate provided by at least one embodiment of the present disclosure;

FIG. 4 is a layout diagram of a display region and a fanout region of a display substrate provided by at least one embodiment of the present disclosure;

FIG. 5 is a schematic plan view corresponding to a first metal layer in FIG. 4;

FIG. 6 is a schematic plan view corresponding to a second metal layer in FIG. 4 provided by at least one embodiment of the present disclosure;

FIG. 7 is a schematic plan view corresponding to an interlayer insulating layer in FIG. 4, which is arranged at a side of a second metal layer away from the base substrate;

FIG. 8 is a schematic plan view corresponding to a first conductive layer in FIG. 4;

FIG. 9 is a schematic plan view corresponding to a first planarization layer in FIG. 4, which is arranged at a side of a first conductive layer away from the base substrate;

FIG. 10 is a schematic plan view corresponding to a second conductive layer in FIG. 4;

FIG. 11 is a schematic plan view corresponding to a second planarization layer in FIG. 4, which is arranged at a side of the second conductive layer away from the base substrate;

FIG. 12 is a schematic plan view corresponding to a third conductive layer in FIG. 4;

FIG. 13 is a schematic plan view of a test unit in a display substrate provided by at least one embodiment of the present disclosure;

FIG. 14 is a schematic plan view of an active layer in FIG. 13;

FIG. 15 is a schematic plan view of a first metal layer in FIG. 13;

FIG. 16 is a schematic plan view of a second metal layer in FIG. 13;

FIG. 17 is a circuit diagram upon a first test switching transistor corresponding to a red sub pixel in FIG. 13 being turned on;

FIG. 18 is a circuit diagram upon a second test switching transistor corresponding to a blue sub pixel in FIG. 13 being turned on;

FIG. 19 is a schematic view of a position of a third via hole structure of an interlayer insulating layer in FIG. 13, which is arranged at a side of a second metal layer away from the active layer;

FIG. 20 is a schematic plan view of a first conductive layer in FIG. 13;

FIG. 21 is a schematic plan view of a third planarization layer in FIG. 13;

FIG. 22 is a schematic plan view of a second conductive layer in FIG. 13;

FIG. 23 is a schematic plan view of a junction of a pad region and a test unit in a display substrate provided by at least one embodiment of the present disclosure;

FIG. 24 is a schematic plan view of a first metal layer in FIG. 23;

FIG. 25 is a schematic plan view of a second metal layer in FIG. 23;

FIG. 26 is a schematic view of a position of a fourth via hole structure of an interlayer insulating layer arranged at a side of a second metal layer away from an active layer in FIG. 23;

FIG. 27 is a schematic plan view of a first conductive layer in FIG. 23;

FIG. 28 is a schematic plan view of a fourth planarization layer in FIG. 23;

FIG. 29 is a schematic plan view of a second conductive layer in FIG. 23;

FIG. 30 is a schematic diagram of an arrangement of data lines, data connection lines and signal transmission lines in a display region and a fanout region in another display substrate provided by at least one embodiment of the present disclosure;

FIG. 31 is a layout diagram of a display region and a fanout region of a display substrate provided by at least one embodiment of the present disclosure;

FIG. 32 is a schematic plan view corresponding to a first metal layer in FIG. 31;

FIG. 33 is a schematic plan view corresponding to a second metal layer in FIG. 31 provided by at least one embodiment of the present disclosure;

FIG. 34 is a schematic plan view corresponding to an interlayer insulating layer in FIG. 31, which is arranged at a side of the second metal layer away from the base substrate;

FIG. 35 is a schematic plan view corresponding to a first conductive layer in FIG. 31;

FIG. 36 is a schematic plan view corresponding to a first planarization layer in FIG. 31, which is arranged at a side of the first conductive layer away from the base substrate;

FIG. 37 is a schematic plan view corresponding to a second conductive layer in FIG. 31;

FIG. 38 is a schematic plan view corresponding to a second planarization layer in FIG. 31, which is arranged at a side of the second conductive layer away from the base substrate;

FIG. 39 is a schematic plan view corresponding to a third conductive layer in FIG. 31;

FIG. 40 is a schematic plan view of a test unit in a display substrate provided by at least one embodiment of the present disclosure;

FIG. 41 is a schematic plan view of an active layer in FIG. 40;

FIG. 42 is a schematic plan view of a first metal layer in FIG. 40;

FIG. 43 is a schematic plan view of a second metal layer in FIG. 40;

FIG. 44 is a circuit diagram upon a first test switching transistor corresponding to a red sub pixel in FIG. 40 being turned on;

FIG. 45 is a circuit diagram upon a second test switching transistor corresponding to a blue sub pixel in FIG. 40 being turned on;

FIG. 46 is a schematic plan view of an interlayer insulating layer in FIG. 31, which is arranged at a side of a second metal layer away from an active layer;

FIG. 47 is a schematic plan view of a first conductive layer in FIG. 31;

FIG. 48 is a schematic plan view of a third planarization layer in FIG. 31;

FIG. 49 is a schematic plan view of a second conductive layer in FIG. 31;

FIG. 50 is a schematic plan view of a junction of a pad region and a test unit in a display substrate provided by at least one embodiment of the present disclosure;

FIG. 51 is a schematic plan view of a first metal layer in FIG. 50;

FIG. 52 is a schematic plan view of a second metal layer in FIG. 50;

FIG. 53 is a schematic view of a position of a fourth via hole structure of an interlayer insulating layer in FIG. 50, which is arranged at a side of the second metal layer away from the active layer;

FIG. 54 is a schematic plan view of a first conductive layer in FIG. 50;

FIG. 55 is a schematic plan view of a fourth planarization layer in FIG. 50;

FIG. 56 is a schematic plan view of a second conductive layer in FIG. 50; and

FIG. 57 is a schematic diagram of a display device provided by an embodiment of the present disclosure.

### DETAILED DESCRIPTION

In order to make the purpose, technical solution and advantages of the embodiments of the present disclosure clear, the technical solution of the embodiments of the disclosure will be described clearly and completely with the attached drawings. Obviously, the described embodiment is a part of the embodiments of the present disclosure, not the whole embodiment. Based on the described embodiments of the present disclosure, all other embodiments obtained by ordinary skilled in the art without creative labor belong to the scope of protection of the present disclosure.

Unless otherwise defined, technical terms or scientific terms used here shall have their ordinary meanings as understood by people with ordinary skills in the field to which this present disclosure belongs. The “first”, “second” and similar words used in the specification and claims of the present disclosure patent application do not indicate any order, quantity or importance, but are only used to distinguish different components. Similar words such as “including” or “containing” mean that the elements or objects appearing before the word cover the elements or objects listed after the word and their equivalents, without excluding other elements or objects. Similar words such as “connecting” or “connected” are not limited to physical or mechanical connection, but can include electrical connection, whether direct or indirect. “Up”, “Down”, “Left” and “Right” are only used to indicate the relative positional relationship. When the absolute position of the described object changes, the relative positional relationship may also change accordingly.

With the development of active matrix organic light emitting diode (AMOLED) display technology, consumers have higher and higher requirements for the display effect of organic light emitting diode (OLED) display devices. Adopting narrow frame design is an important measure to improve the display effect of the OLED display devices, and an important technology to realize narrow frame is FIP (Fanout In Pixel) technology. In the structure of an OLED display device with the narrow frame realized by the FIP technology, the arrangement order of data signal lines connected with the sub pixels is staggered, which may lead to that the data signal lines of the fanout region connected with the sub pixel with the same color may be located in different film layers, and the loads of the data signal lines connected with the sub pixels with the same color are different due to different parasitic capacitances between different film layers. Therefore, the signal writing amount of the data signal lines connected with the sub pixels with the same color is different, and finally the display brightness of the OLED display device is different, which will further affect the display quality of the whole OLED display device.

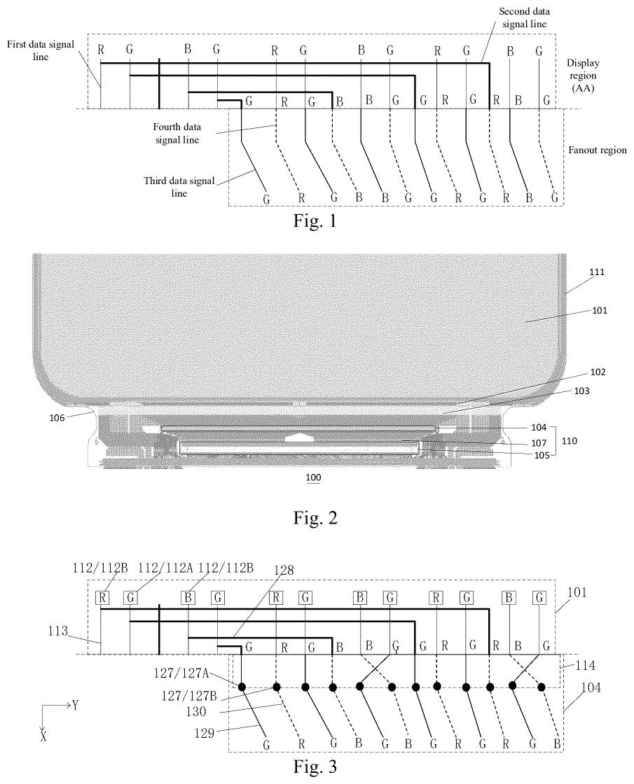

For example, FIG. 1 is a schematic diagram of an arrangement of data signal lines in a display region and a fanout region in a display substrate. As illustrated by FIG. 1, the thinner traces in the display region (AA) are conventional first data signal lines, and the thicker traces are second data signal lines inserted by a FIP mode. The solid lines in the fanout region represent third data signal lines arranged on a first gate metal layer, and the dotted lines represent fourth data signal lines arranged on the second gate metal layer, and the first gate metal layer and the second gate metal layer are different metal layers. In the display region (AA), the sub pixels connected with the first data signal lines from left to right are red sub pixel (R), green sub pixel (G), blue sub pixel (B), green sub pixel (G), red sub pixel (R), green sub pixel (G), blue sub pixel (B), green sub pixel (G), red sub pixel (R), green sub pixel (G), blue sub pixel (B), green sub pixel (G), that is, 12 sub pixels arranged in an order of RGBGRGBGRGBG to form a cycle; and the arrangement of the third data signal lines connected with the sub pixels is also represented by symbols such as R, G and B, which refers to the actual arrangement of the data signal lines connected with the sub pixels with different colors. In FIG. 1, in a display region (AA), two adjacent first data signal lines form a first group of first data signal lines, and two other first data signal lines which are adjacent to the first group of first data signal lines form a second group of first data signal lines. A second data signal line is inserted between the first group of first data signal lines and the second group of first data signal lines, and at an edge position, no second data signal line is inserted between the two adjacent groups of the first group of first data signal lines. By inserting the second data signal line between the first group of first data signal lines and the second group of first data signal lines, the arrangement order of data signal lines (including the third data signal lines and the fourth data signal lines) in the fanout region is changed, that is, in the display region (AA), the arrangement order of the first data signal lines is different from the arrangement order of the third data signal lines and the fourth data signal lines in the fanout region. For example, in the fanout region of FIG. 1, the third data signal lines arranged at odd-numbered positions are located in the first gate metal layer, and the fourth data signal lines arranged at even-numbered positions are located in the second gate metal layer. That is, from left to right, the first one of the third data signal lines connected with the green sub pixel G, the third one of the third data signal lines connected with the green sub pixel G, the fifth one of the third data signal lines connected with the blue sub pixel B, the seventh one of the third data signal lines connected with the green sub pixel G, the ninth one of the third data signal lines connected with the green sub pixel G, and the eleventh one of the third data signal lines connected with the blue sub pixel B are located in the first gate metal layer; the second one of the fourth data signal lines connected with the red sub pixel R, the fourth one of the fourth data signal lines connected with the blue sub pixel B, the sixth one of the fourth data signal lines connected with the green sub pixel G, the eighth one of the fourth data signal lines connected with the red sub pixel R, the tenth one of the fourth data signal lines connected with the red sub pixel R, and the twelfth one of the fourth data signal lines connected with the green sub pixel G are located in the second gate metal layer, and every twelve data signal lines form one cycle. That is, in the fanout region, the arrangement order of the twelve data signal lines is GRGBBGGRGRBG; the sixth one of the fourth data signal lines connected with the green sub pixel G and the twelfth one of the fourth data signal lines connected with the green sub pixel G are both located in the second gate metal layer, and the rest third data signal lines connected with the green sub pixels G are located in the first gate metal layer, In this way, the data signal lines connected with the sub pixels of the same color are located in different layers, which easily leads to the case that different parasitic capacitances between different film layers, resulting in different loads of different film layers, which will lead to different signal writing amounts of data signal lines connected with the sub pixels of the same color, and ultimately lead to different display brightness of OLED display devices, thus affecting the display quality of the whole OLED display device.

The inventor(s) of the present disclosure has noticed that when the parasitic capacitances of the first gate metal layer and the second gate metal layer are different, the resistances of the third data signal line and the fourth data signal line respectively connected with the green sub pixels G will be different, which will lead to the problem that the display brightness of the display device is different. Therefore, it can be considered that by performing a jumper design on the data signal lines at the position of the fanout region close to the display region (AA), that is, by changing the arrangement order of data signal lines in the fanout region is changed, the data signal lines connected with sub pixels of the same color are adjusted to be located in the same film layer, so as to avoid the difference in parasitic capacitance caused by different film layers of data signal lines connected with the sub pixels of the same color, and further avoid the problem that the data signal writing amount is different due to different loads of data signal lines connected with sub pixels of the same color, that is, the influence caused by different parasitic capacitances can be avoided, and the subsequent connection order of data signal lines in the driving circuit will not be affected.

At least one embodiment of the present disclosure provides a display substrate. The display substrate includes a base substrate, which is divided into a display region and a peripheral region surrounding the display region, the peripheral region includes a fanout region adjacent to the display region and a pad region at a side of the fanout region away from the display region; a plurality of sub pixels arranged in a matrix and arranged in the display region, and each column of the plurality of sub pixels being connected with a data line; the fanout region includes a connection region adjacent to the display region, a part of data lines being directly connected with the connection pads located in the connection region, and other part of the data lines being connected with the connection pads located in the connection region through data connection lines; the plurality of sub pixels include a plurality of columns of first color sub pixels and a plurality of columns of second color sub pixels, and the connection pads comprise a plurality of first connection pads and a plurality of second connection pads, the plurality of first connection pads are electrically connected with the plurality of columns of first color sub pixels and the plurality of second connection pads are electrically connected with the plurality of columns of second color sub pixels; a plurality of first signal transmission lines and a plurality of second signal transmission lines arranged at intervals in positions of the fanout region close to the pad region, the plurality of first signal transmission lines are arranged in a first metal layer, and the plurality of second signal transmission lines are arranged in a second metal layer which is different from the first metal layer; the plurality of first signal transmission lines and the plurality of first connection pads are electrically connected in one-to-one correspondence, and the plurality of second signal transmission lines and the plurality of second connection pads are electrically connected in one-to-one correspondence; two adjacent data connection lines of the data connection lines and at least two data lines of the data lines which are located between the two adjacent data connection lines are taken as a data line group, connection pads connected with at least two data lines in one data line group at least include one first connection pad and one second connection pad, and in at least one data line group, an orthographic projection of a data line connected with the second connection pad on the base substrate and an orthographic projection of a signal transmission line connected with the first connection pad on the base substrate has an overlapping part in the fanout region, or, connection pads respectively connected with the at least two data lines and the two adjacent data connection lines in the data line group include a first connection pad and a second connection pad, and in at least one data line group, one data connection line of the two adjacent data connection lines is electrically connected with the first connection pad or the second connection pad through a connection electrode, and an orthographic projection of the connection electrode on the base substrate and an orthographic projection of a data line, which is adjacent to the data connection line connected with the connection electrode, on the base substrate has an overlapping part in the fanout region.

For example, the display substrate is subjected to a jumper design on data lines and data lines or a jumper design on data lines and data connection line at the connection region of the fanout region adjacent to the display region (AA), that is, the arrangement order of sub pixels connected with data lines and data connection lines at the position of the display region close to the fanout region is different from the arrangement order of the sub pixels connected with the first connection pads and the second connection pads at the position of the fanout region away from the display region, so that the signal transmission lines (including the first signal transmission lines and the second signal transmission lines) connected with the sub pixels of the same color in the fanout region are adjusted to be located in the same film layer, so as to avoid the difference in parasitic capacitance caused by different film layers of the signal transmission lines connected with sub pixels of the same color, and further avoid the problem that different loads of the signal transmission lines connected with sub pixels of the same color cause different data signal writing amounts.

For example, FIG. 2 is a schematic plan view of a display substrate provided by at least one embodiment of the present disclosure. As illustrated by FIG. 2, the display substrate 100 includes a display region 101 and a peripheral region 110, the peripheral region 110 includes a fanout region 104 adjacent to the display region 101 and a pad region 105 at a side of the fanout region 104 away from the display region 101. The fanout region 104 can be used as a test region, and a driving circuit is arranged in the pad region 105. The location of a junction of the fanout region 104 and the display region 101 is the location shown by a connection region 102. The inventor(s) of the present disclosure has noticed that at least at the location of the junction of the fanout region 104 and the display region 101, that is, the connection region 102, needs to be subjected to a jumper design on data lines and data lines or data lines and data connection lines.

For example, a planar shape of the display region 101 can be rectangular, and an edge of the display region 101 can be a circular arc shape. For example, in the plan view shown in FIG. 2, the display region 101 has a rectangular shape with rounded corners, but the embodiment of the present disclosure is not limited thereto, and the display region can also be rectangular or other special-shaped structures.

For example, the display region 101 is used for displaying an image, although not shown in FIG. 2, a plurality of data lines, a plurality of scanning lines, a plurality of horizontal transmission lines, a plurality of vertical transmission lines and light emission control signal lines are provided in the display region 101. Any one of the vertical transmission lines may be arranged between two data lines adjacent to each other, and the vertical transmission lines may be arranged parallel to the data lines. A cathode power supply voltage for driving a light emitting structure of a display substrate may be applied to a vertical transmission line, and the vertical transmission line is connected with an access terminal connecting the cathode power supply voltage to the display region at the peripheral position, to transmit the cathode power supply voltage to a corresponding sub pixel. The plurality of horizontal transmission lines are connected with the data lines to transmit data voltages to the data lines, and each of the data lines is connected with a plurality of sub pixels located in the same column to provide data signals or data voltages to corresponding sub pixels in the display region. The data line and the vertical transmission lines are located in the same film layer, and the horizontal transmission lines and the vertical transmission lines are located in different film layers. The horizontal transmission line is electrically connected with the data line through a first via hole structure to transmit the data voltage to the data line. The scanning line may be arranged in parallel with the light emission control signal line and the horizontal transmission line, and the scanning line, the data line and the light emission control signal line may be electrically connected with each sub pixel. Each sub pixel includes an organic light emitting diode, a first transistor to an n-th transistor, and a storage capacitor.

For example, the peripheral region 110 may include a left peripheral region adjacent to a left side of the display region 101, a right peripheral region adjacent to a right side of the display region 101, an upper peripheral region adjacent to an upper side of the display region 101, and a lower peripheral region adjacent to a lower side of the display region 101. Because the data pads and the gate pads for connecting driving parts are arranged in the lower peripheral region, the lower peripheral region can have a larger area. For example, the lower peripheral region has a width greater than the widths of the upper peripheral region, the left peripheral region and the right peripheral region. It should be noted that the widths of the upper peripheral region, the lower peripheral region, the left peripheral region and the right peripheral region refer to the minimum distances between the edges of the upper peripheral region, the lower peripheral region, the left peripheral region and the right peripheral region adjacent to the display region and the edges farthest from the display region, respectively. Unless otherwise specified below, the following peripheral region refers to the lower peripheral region provided with the data pads and the gate pads.

For example, FIG. 2 mainly shows the lower peripheral region, and the lower peripheral region includes a fanout region 104 adjacent to the display region 101 and a pad region 105 at a side of the fanout region 104 away from the display region 101, and the data pads and the gate pads are arranged in the pad region 105. Peripheral lines for transmitting the cathode power supply voltage (e.g., low power supply voltage) of the OLED are arranged in the lower peripheral region, and the peripheral lines may be connected with each of the vertical transmission lines. A chip of a data driving component may be connected with the data pads, and for example, a driving substrate including a timing control component may be connected with the gate pads.

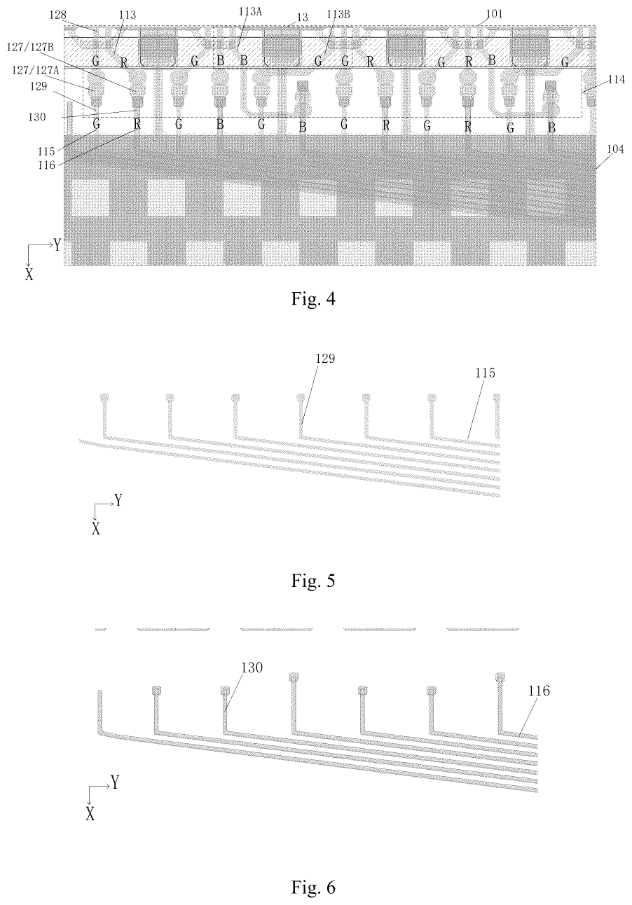

For example, FIG. 3 is a schematic diagram of an arrangement of data lines, data connection lines and signal transmission lines in a display region and a fanout region in a display substrate provided by at least one embodiment of the present disclosure, and FIG. 4 is a layout diagram of a display region and a fanout region of a display substrate provided by at least one embodiment of the present disclosure. For example, as illustrated by FIG. 2, FIG. 3, and FIG. 4, the display substrate 100 includes a base substrate 111, and the base substrate 111 includes a display region 101 and a peripheral region 110 surrounding the display region 101. The peripheral region 110 includes a fanout region 104 adjacent to the display region 101 and a pad region 105 at a side of the fanout region 104 away from the display region 101. The display region 101 is provided with a plurality of sub pixels 112 arranged in a matrix, and the plurality of sub pixels 112 are arranged to form a plurality of columns of sub pixels, and the plurality of columns of sub pixels 112 are electrically connected with a plurality of data lines 113 in one-to-one correspondence, that is, each column of sub pixels 112 is connected with a data line 113. The fanout region 104 includes a connection region 114 adjacent to the display region 101. A part of the data lines 113 are directly connected with the connection pads 127 located in the connection region 114, and the other part of the data lines 113 are connected with the connection pads 127 located in the connection region 114 through data connection lines 128. The plurality of sub pixels 112 include a plurality of columns of first color sub pixels 112A and a plurality of columns of second color sub pixels 112B, and the connection pads 127 include a plurality of first connection pads 127A and a plurality of second connection pads 127B, the plurality of first connection pads 127A are electrically connected with a plurality of columns of first color sub pixels 112A and the plurality of second connection pads 127B are electrically connected with a plurality of columns of second color sub pixels 112B. There are a plurality of first signal transmission lines 129 and a plurality of second signal transmission lines 130 arranged at intervals in positions of the fanout region 104 close to the pad region 105, the first signal transmission lines 129 are arranged in a first metal layer 115 and the second signal transmission lines 130 are arranged in a second metal layer 116 which is different from the first metal layer 115; the plurality of first signal transmission lines 129 and the plurality of first connection pads 127A are electrically connected in one-to-one correspondence, and the plurality of second signal transmission lines 130 and the plurality of second connection pads 127B are electrically connected in one-to-one correspondence, so that two adjacent data connection lines 128 and at least two data lines 113 located between the two adjacent data connection lines 128 form a data line group 13. The connection pads 127 connected with the at least two data lines 113 in one data line group 13 at least include one first connection pad 127A and one second connection pad 127B, and in at least one data line group 13, an orthographic projection of a data line 113 connected with the second connection pad 127B on the base substrate and an orthographic projection of a first signal transmission line 129 connected with the first connection pad 127A on the base substrate 111 have an overlapping part in the fanout region 104.

For example, as illustrated by FIG. 2, FIG. 3 and FIG. 4, a plurality of data lines 113 and a plurality of data connection lines 128 are arranged on the base substrate 111, extend in the first direction X in the display region 101 and are arranged in the second direction Y intersecting with the first direction X, the plurality of data lines 113 and the plurality of data connection lines 128 extend from the display region 101 to the fanout region 104, at a position of the display region 101 close to the fanout region 104, a part of the plurality of data lines 113 is arranged in odd-numbered columns, the other part of the plurality of data lines 113 is arranged in even-numbered columns, and a part of the plurality of data connection lines 128 is arranged in even-numbered columns and the other part of the plurality of data connection lines 128 is arranged in odd-numbered columns. The fanout region 104 includes a connection region 114 adjacent to the display region 101, in other regions of the fanout region 104 except the connection region 114, a plurality of first signal transmission lines 129 and a plurality of second signal transmission lines 130 are arranged in the second direction Y, and one kind of the first signal transmission lines 129 and the second signal transmission lines 130 is arranged in odd-numbered columns, and the other kind of the plurality of first signal transmission lines 129 and the plurality of second signal transmission lines 130 is arranged in even-numbered columns, the plurality of first signal transmission lines 129 are arranged in the first metal layer 115, and the plurality of second signal transmission lines 130 are arranged in the second metal layer 116 which is different from the first metal layer 115. This design can make the arrangement order of the sub pixels connected with the data line 113 and the data connection line 128 at the position of the display region 101 close to the fanout region 104 different from the arrangement order of the sub pixels connected with the first signal transmission lines 129 and the second signal transmission lines 130 at the position of the fanout region 104 away from the display region 101, so as to adjust the plurality of first signal transmission lines 129 or the plurality of second signal transmission lines 130 connected with the sub pixels of the same color to be located in the same film layer, so as to avoid different parasitic capacitances caused by different film layers of the plurality of first signal transmission lines 129 or the plurality of second signal transmission lines 130 connected with the sub pixels of the same color, and further avoid the problem that different loads of the plurality of first signal transmission lines 129 or the plurality of second signal transmission lines 130 connected with the sub pixels of the same color cause different data signal writing amounts.

For example, as illustrated by FIG. 3, the data lines 113 and the data connection lines 128 are arranged in a third conductive layer, and the connection pads 127 connected with two adjacent data lines 113 in one data line group 13 are a first connection pad 127A and a second connection pad 127B, respectively. A first data line 113A (e.g., a third data line connected with a red sub pixel) in two adjacent data lines 113 in one data line group 13 crosses a first signal transmission line 129 connected with a second data line 113B (e.g., a fourth data line connected with a green sub pixel) that is adjacent to the first data line 113A in an even-numbered column. For example, the second data line 113B located in the even-numbered column extends to a side of a junction of the display region 101 and the fanout region 104 close to the adjacent first data line 113A, so as to be electrically connected with a corresponding first signal transmission line 129.

For example, in one example, the first color sub pixel 112A is a green sub pixel G, and the second color sub pixel 112B is a red sub pixel R or a blue sub pixel B. For example, as illustrated by FIG. 3, the data line 113 and the data connection line 128 are sequentially arranged as a whole at the position of the display region 101 close to the fanout region 104 along the first direction X, and along the second direction Y, a data connection line 128 (first data connection line) connected with the green sub pixel G, a data line 113 (first data line) connected with the red sub pixel R, a data line 113 (second data line) connected with the green sub pixel G, a data connection line 128 (second data connection line) connected with the blue sub pixel B, a data line 113 (third data line) connected with the blue sub pixel B, a data line 113 (fourth data line) connected with green sub pixel G, a data connection line 128 (third data connection line) connected with green sub pixel G, a data line 113 (fifth data line) connected with red sub pixel R, a data line 113 (sixth data line) connected with green sub pixel G, a data connection line 128 (fourth data connection line) connected with red sub pixel R and a data line 113 (seventh data line) connected with the blue sub pixel B, and a data line 128 (eighth data line) connected with the green sub pixel G are arranged in sequence. That is, in this example, the first data connection line, the second data line, the third data line, the third data connection line, the sixth data line and the seventh data line are arranged in odd-numbered columns, and the first data line, the second data connection line, the fourth data line, the fifth data line, the fourth data connection line and the eighth data line are arranged in even-numbered columns.

It should be noted that, the data connection line is inserted in FIP mode, so that the data line connected with the data connection line is connected with the corresponding connection pad through the data connection line.

For example, in FIG. 3, in other regions of the fanout region 104 except the connection region 114, the plurality of first signal transmission lines 129 are arranged in odd-numbered columns, and the plurality of second signal transmission lines 130 are arranged in even-numbered columns. The plurality of first signal transmission lines 129 are all electrically connected with a plurality of first connection pads 127A in one-to-one correspondence, and are electrically connected with the first color sub pixels 112A in one-to-one correspondence. The plurality of second signal transmission lines 130 are electrically connected with a plurality of second connection pads 127B in one-to-one correspondence, and are all electrically connected with a plurality of second color sub pixels 112B in one-to-one correspondence. The plurality of first signal transmission lines 129 are arranged in the first metal layer 115, and the plurality of second signal transmission lines 130 are arranged in the second metal layer 116 which is located in a different layer from the first metal layer 115. That is, the display substrate performs a jumper design to the data lines at the connection region of the fanout region that is directly adjacent to the display region (AA), so that the arrangement order of the sub pixels connected with the data lines and the data connection lines at the positions of the display region close to the fanout region is different from the arrangement order of the sub pixels connected with the plurality of first signal transmission lines and the plurality of second signal transmission lines at the position of the fanout region away from the display region, so as to adjust the plurality of first signal transmission lines or the plurality of second signal transmission lines connected with the sub pixels of the same color to be located in the same film layer, so as to avoid different parasitic capacitances caused by different film layers of the first signal transmission lines or the second signal transmission lines connected with the sub pixels of the same color, and further avoid the problem that different loads of the first signal transmission lines or the second signal transmission lines connected with the sub pixels of the same color cause different data signal writing amounts.

It should be noted that, the first data line to the eighth data line refer to an order sorting the data lines located in the same row as the data connection lines, and the first data connection line to the fourth data connection line refers to an order sorting the data connection lines inserted in FIP mode in sequence. The first data line to the eighth data line and the first data connection line to the fourth data connection line are taken from the data lines and the data connection lines, respectively, only for the convenience of description, and do not refer to other data lines except the data lines and the data connection lines.

It should also be noted that, the above-mentioned jumper design to data lines refers to swapping the positions of two adjacent data lines, switching an odd-numbered data line among the two data lines to an even-numbered data line, and switching the even-numbered data line to the odd-numbered data line, and the two data lines still maintain the adjacent position relationship. Specifically, it can be realized by crossing the data lines located in different layers at positions corresponding to the connection region on the plane.

For example, as illustrated by FIG. 4, in other regions of the fanout region 104 except the connection region 114, 12 signal transmission lines arranged in sequence along the second direction Y are described as a cycle, and the 12 signal transmission lines in one cycle include a plurality of first signal transmission lines 129 and a plurality of second signal transmission lines 130. In FIG. 4, the first signal transmission lines 129 are all arranged in odd-numbered columns, and the second signal transmission lines 130 are all arranged in odd-numbered columns.

For example, as illustrated by FIG. 4, in the fanout region 104, a first connection pad 127A connected with the green sub pixel G, a second connection pad 127B connected with the red sub pixel R, a first connection pad 127A connected with the green sub pixel G, a second connection pad 127B connected with the blue sub pixel B, a first connection pad 127A connected with the green sub pixel G, and a second connection pad 127B connected with the blue sub pixel B, a first connection pad 127A connected with the green sub pixel G, a second connection pad 127B connected with the red sub pixel R, a first connection pad 127A connected with the green sub pixel G, a second connection pad 127B connected with the red sub pixel R, a first connection pad 127A connected with the green sub pixel G and a second connection pad 127B connected with the blue sub pixel B are sequentially arranged along the second direction Y. The plurality of first connection pads 127A and the plurality of first signal transmission lines 129 are electrically connected in one-to-one correspondence, and the plurality of second connection pads 127B and the plurality of second signal transmission lines 130 are electrically connected in one-to-one correspondence, so that the plurality of first signal transmission lines 129 can be arranged in the first metal layer 115, and the plurality of second signal transmission lines 130 can be arranged in the second metal layer 116 which is located in a different layer from the first metal layer 115. In this way, signal transmission lines connected with the sub pixels of the same color can be adjusted to be located in the same film layer, so as to avoid different parasitic capacitances caused by different film layers of signal transmission lines connected with the sub pixels of the same color, and further avoid the problem that different loads of signal transmission lines connected with the sub pixels of the same color cause different data signal writing amounts.

For example, in combination with FIG. 2 and FIG. 4, the display region 101 may include a plurality of thin film transistors, at least one of the plurality of thin film transistors may have a double-gate structure. For example, the first thin film transistor includes a first gate electrode and a second gate electrode, and all other thin film transistors have only one gate electrode. The first metal layer 115 may be formed in the same layer as the first gate electrode of the first thin film transistor, and the second metal layer 116 may be formed in the same layer as the second gate electrode of the first thin film transistor. In a direction perpendicular to a main surface of the base substrate 111, although not shown in FIG. 4, there is also an insulating layer between the first metal layer 115 and the second metal layer 116, which can prevent electrical communication between the data lines 113 having an overlapping part on the plane parallel to the main surface of the base substrate 111 in the connection region 114.

For example, as illustrated by FIG. 4, upon the parasitic capacitance of the first metal layer 115 and the second metal layer 116 changing, the resistance of the first signal transmission line 129 connected with the green sub pixel G will be different, which will lead to the difference in display brightness of the display device. Therefore, in the embodiment of the present disclosure, in the connection region 114, a jumper design is performed on the third data line 113 connected with the blue sub pixel B and the fourth data line 113 connected with the green sub pixel G, and a jumper design is performed on the seventh data line 113 connected with the blue sub pixel B and the eighth data line 113 connected with the green sub pixel G, so that the green sub pixel G is still connected with the first signal transmission line 129 located in the first metal layer 115, and the blue sub pixel B is still connected with the second signal transmission line 130 located in the second metal layer 116. After connection, in other regions of the fanout region 104 except the connection region 114, the arrangement order of the sub pixels connected with a plurality of signal transmission lines is GRGBGB GRGRGB, so that the first signal transmission lines 129 connected with the green sub pixel G are all arranged in odd-numbered columns (the first signal transmission lines 129 and the second signal transmission lines 130 connected with the sub pixels in FIG. 4 are sorted as a whole) and located in the first metal layer 115, and the second signal transmission lines 130 connected with the blue sub pixel B or the red sub pixel R are all arranged in even-numbered columns (the first signal transmission lines 129 and the second signal transmission lines 130 connected with the sub pixels in FIG. 4 are sorted as a whole) and located in the second metal layer 116, so as to avoid the influence of the parasitic capacitance.

For example, FIG. 5 is a schematic plan view corresponding to a first metal layer in FIG. 4. As illustrated by combination with FIG. 4 and FIG. 5, in other regions of the fanout region 104 except the connection region 114, a plurality of first signal transmission lines 129 in the first metal layer 115 all have the shape of a folded line, and each of the first signal transmission lines 129 includes a vertical part extending along the first direction X, and then an oblique part extending along a direction at an obtuse angle to the first direction X, and the oblique part will eventually make the first signal transmission line 129 shrink inward to the middle region. Vertical portions of the plurality of first signal transmission lines 129 are uniformly distributed in the second direction Y, so that signals transmitted to the first signal transmission lines 129 are more uniform.

For example, FIG. 6 is a schematic plan view corresponding to a second metal layer in FIG. 4 provided by at least one embodiment of the present disclosure. Combining with FIG. 4 and FIG. 6, in other regions of the fanout region 104 except the jumper position, a plurality of second signal transmission lines 130 in the second metal layer 116 have the shape of a folded line and each of the plurality of second signal transmission lines 130 includes a vertical part extending along the first direction X, and then an oblique line extending along a direction at an obtuse angle to the first direction X, and the oblique part will eventually make the second signal transmission line 130 shrink inward to the middle region. The vertical portions of the plurality of second signal transmission lines 130 are uniformly distributed in the second direction Y, so that signals transmitted to the second signal transmission lines 130 are more uniform. Ignoring the leftmost second signal transmission line in FIG. 6 which is not connected with the sub pixel, the lengths of the vertical parts of the third one and the sixth one of the second signal transmission lines 130 are greater than the lengths of the vertical parts of other second signal transmission lines 130 along the second direction Y. This design is to realize the jumper design of the above- mentioned adjacent first signal transmission lines 129 and second signal transmission lines 130, and this design will not increase the process steps.

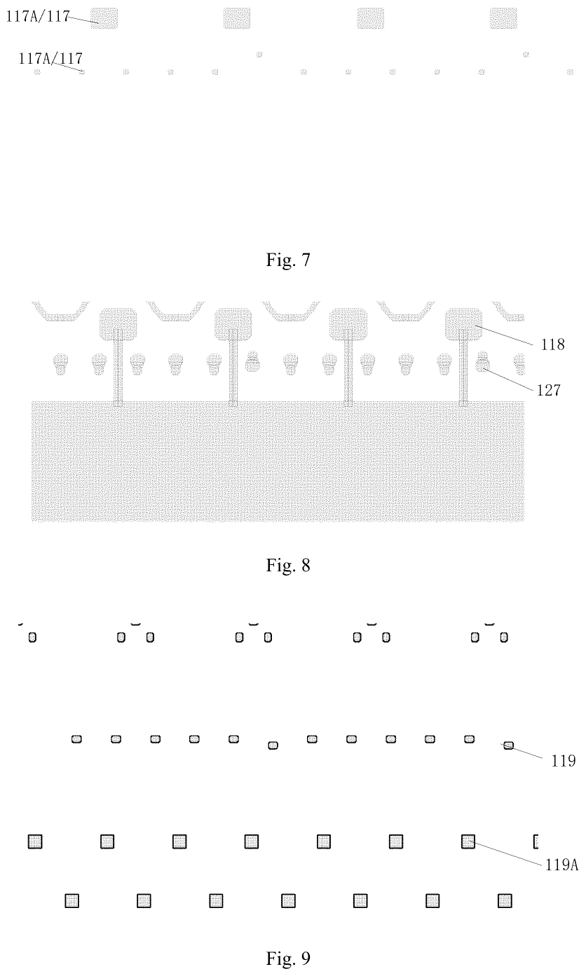

For example, FIG. 7 is a schematic plan view corresponding to an interlayer insulating layer in FIG. 4, which is arranged at a side of a second metal layer away from the base substrate. As illustrated by FIG. 7, the interlayer insulating layer 117 is provided with a plurality of first hole structures 117A, and the plurality of first hole structures 117A can realize the electrical connection between the structure arranged at a side of the interlayer insulating layer 117 away from the base substrate 111 and the structure of the interlayer insulating layer 117 close to the base substrate 111.

For example, FIG. 8 is a schematic plan view corresponding to a first conductive layer in FIG. 4. As illustrated by FIG. 8, the connection pads 127 include a double-layer structure, and a plurality of first connectors 118A included in the first conductive layer 118 can be used as a layer structure of the connection pads 127 close to the base substrate 111, and cooperate with the second connectors mentioned later to realize that a plurality of data lines 113 or a plurality of data connection lines 128 located in the display region 101 are connected with a plurality of corresponding first signal transmission lines 129 and a plurality of corresponding second signal transmission lines in the fanout region 104. The material of the first conductive layer 118 may be a conductive metal or a conductive metal oxide, as long as a stable connection relationship can be satisfied, which is not limited by the embodiment of the present disclosure.

For example, FIG. 9 is a schematic plan view corresponding to a first planarization layer in FIG. 4, which is arranged at a side of a first conductive layer away from the base substrate. As illustrated by FIG. 9, a plurality of second hole structures 119A are arranged in the first planarization layer 119, and the plurality of second hole structures 119A are used to connect the first conductive layer 118 and the second conductive layer at a side of the first planarization layer 119 away from the base substrate 111.

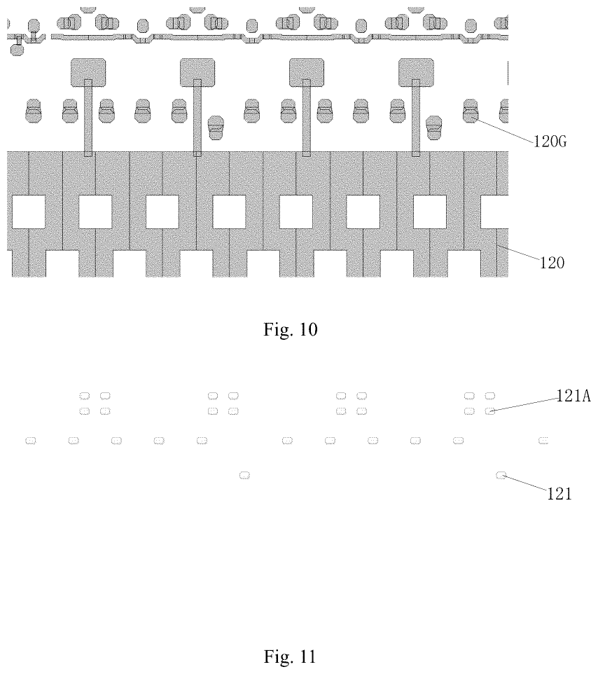

For example, FIG. 10 is a schematic plan view corresponding to a second conductive layer in FIG. 4. As illustrated by FIG. 10, a plurality of second connectors 120G included in the second conductive layer 120 can be used as a layer structure of the connection pads 127 away from the base substrate 111, and the plurality of second connectors 120G and the first connectors 118A are used to connect the data lines 113 or the plurality of data connection lines 128 with a plurality of corresponding first signal transmission lines 129 or a plurality of corresponding second signal transmission lines 130.

For example, FIG. 11 is a schematic plan view corresponding to a second planarization layer in FIG. 4, which is arranged at a side of the second conductive layer away from the base substrate. As illustrated by FIG. 11, a plurality of third hole structures 121A are arranged in the second planarization layer 121, and the plurality of third hole structures are used to connect the second conductive layer 120 and the third conductive layer at a side of the second planarization layer 121 away from the base substrate 111.

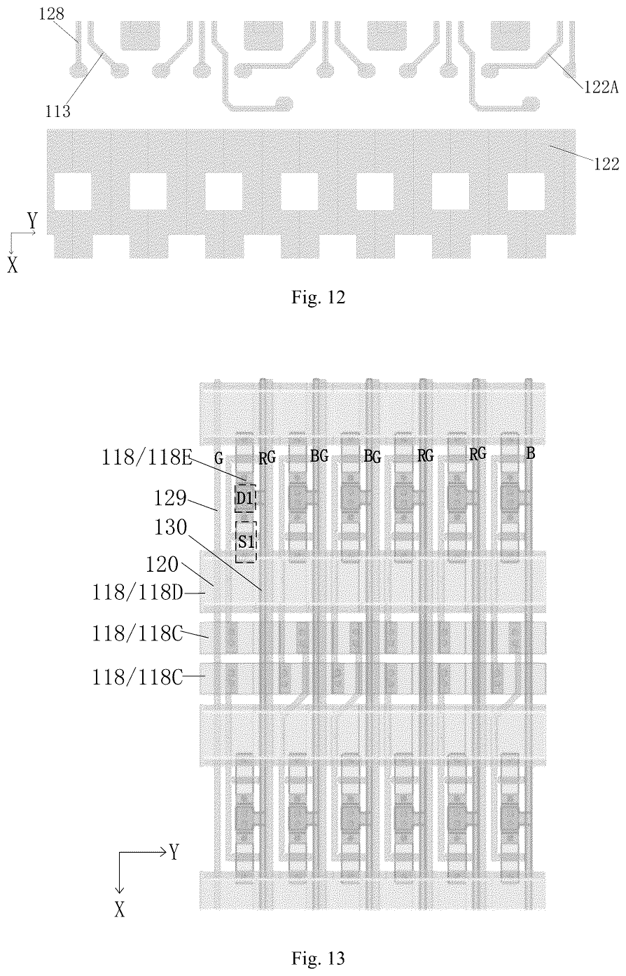

For example, FIG. 12 is a schematic plan view corresponding to a third conductive layer in FIG. 4. As illustrated by FIG. 12, the third conductive layer 122 includes a plurality of data lines 113 and a plurality of data connection lines 128. It can be seen from FIG. 12, along the second direction Y, a plurality of data lines 113 and a plurality of data connection lines 128 are sorted, which are a first data connection line, a first data line, a second data connection line, a third data line, a fourth data line, a third data connection line, a fifth data line, a sixth data line, a fourth data connection line, a seventh data line and an eighth data line in turn. That is, the first data connection line 128 refers to the data connection line arranged at the first position among the four data connection lines, that is, the first one of the data connection lines 128, and the second data connection line 128 to the fourth data connection line 128 have similar definitions; the first data line 113 refers to the data line arranged at the first position among the eight data lines, that is, the first one of the data lines 113, and the second data line 113 to the eighth data line 113 have similar definitions.

For example, as illustrated by FIG. 12, the first one of the first data connection lines 128 extends along the first direction X; the first data line 113 extends along the first direction X and then obliquely to the lower right corner; the second data line 113 extends along the first direction X and then obliquely to the lower left corner; the second data connection line 128 extends along the first direction X; the third data line 113 firstly bends and extends in the first direction X, and then extends in the second direction Y to form a hook-shaped or non-closed quadrilateral; the fourth data line 113 firstly bends and extends along the first direction X, and then extends along a direction opposite to the second direction; the third data connection line 128, the fifth data line 113, the sixth data line 113, the fourth data connection line 128, the seventh data line 113 and the eighth data line 113 sequentially repeat the shapes of the first data connection line 128, the first data line 113, the second data line 113, the second data connection line 128, the third data line 113 and the fourth data line 113, and the details thereof are not repeated herein.

For example, in one example, as illustrated by FIG. 2, FIG. 4 and FIG. 12, the third data line 113 and the seventh data line 113 respectively extend to a side close to the pad region 105 in the fanout region 104, and then extend in directions of the fourth data line 113 and the eighth data line 113 adjacent thereto to form an L-shaped structure or an inverted L-shaped structure, and the fourth data line 113 first extends in a direction approaching the third data line, then extends to a side close to the pad region 105 to form an unclosed quadrilateral with the third data line 113, that is, the unclosed quadrilateral is unclosed at the right side to have an opening; the eighth data line 113 first extends in a direction close to the seventh data line 113, and then extends to a side close to the pad region 105 to form an unclosed quadrilateral with the seventh data line 113, that is, the unclosed quadrilateral is unclosed at the right side to have an opening.

For example, as illustrated by FIG. 4, a first data line 113A located in an odd-numbered column (e.g., the third data line connected with the red sub pixel) first extends to a side close to the pad region 105 in the fanout region 104, and then extends in a direction of the second data line 113B located in an even-numbered column (e.g., the fourth data line connected with the green sub pixel) adjacent thereto to form an L-shaped structure or an inverted L-shaped structure. The second data line 113B located in the even-numbered column extends in a direction close to the first data line 113A in the fanout region 104, and then extends to a side close to the pad region 105 to form an unclosed quadrilateral with the first data line 113A.

For example, as illustrated by FIG. 2, FIG. 4 and FIG. 12, the third data line 113 and the seventh data line 113 connected with the blue sub pixels B first extend along the second direction Y and then extend along the first direction X, so that L-shape structures can be formed, and the corresponding fourth data line 113 and the eighth data line 113 connected with the green sub pixels G extend in an opposite direction to the second direction Y; alternatively, the third data line 113 and the seventh data line 113 connected with the blue sub pixels B may first extend in the direction opposite to the second direction Y, and then extend in the first direction X to form inverted L shape structures, and the corresponding fourth data line 113 and the eighth data line 113 connected with the green sub pixels G may extend in the second direction Y.

For example, as illustrated by FIG. 4 and FIG. 12, the third data line 113 connected with the blue sub pixel B crosses a first signal transmission line 129 connected with the fourth data line 113 adjacent thereto, so as to be electrically connected with a second signal transmission line 130 corresponding to the third data line 113. And, the fourth data line 113 extends to a side of the third data line 113 adjacent thereto at a junction of the display region 101 and the fanout region 104, so as to be electrically connected with the corresponding first signal transmission line 129, that is, the third data line 113 crosses with the first signal transmission line 129 connected with the fourth data line 113 adjacent thereto, and the fourth data line 113 does not cross with the first signal transmission line 129 electrically connected with the third data line 113 adjacent thereto. For example, the third data line 113 crosses the first signal transmission line 129 connected with the fourth data line 113, so that the third data line 113 connected with the blue sub pixel B is electrically connected with the corresponding second signal transmission line 130, and the fourth data line 113 extends in a direction opposite to the second direction Y, so as to be electrically connected with the corresponding first signal transmission line 129, that is, the first signal transmission line 129 is also connected with the green sub pixel G. For example, in FIG. 4, the third data line 113 is wound around the connection pad from a position close to a wiring region in the display region through the third conductive layer, and the fourth data line 113 is connected with the connection pad from a position away from the wiring region in the display region through the third conductive layer, that is, the third data line 113 crosses the first signal transmission line 129 connected with the fourth data line 113, but the fourth data line 113 and the second signal transmission line 130 connected with the third data line 113 do not cross with each other. Because only the third data line 113 located in the third conductive layer and connected with the blue sub pixel B overlaps with the first signal transmission line 129 connected with the green sub pixel G, there is no overlap between the fourth data line 113 connected with the green sub pixel G and the second signal transmission line 130 connected with the blue sub pixel, so that parasitic capacitance can be reduced, which can minimize the capacitance difference between different signal layers caused by jumper wires.

For example, as illustrated by FIG. 4, on a plane parallel to the main surface of the base substrate 111, a first data line 113A (for example, the third data line connected with a red sub pixel) and a first signal transmission line 129 connected with a second data line 113B (for example, the fourth data line connected with a green sub pixel) cross with each other; the second data line 113B and the second signal transmission line 130 electrically connected with the first data line 113A do not cross with each other.

It should be noted that, the crossing of the third data line and the first signal transmission line connected with the fourth data line refers to that the third data line and the first signal transmission line connected with the fourth data line overlap with each other on the plane parallel to the main surface of the base substrate 111, that is, an orthographic projection of the third data line on the base substrate and an orthographic projection of the first signal transmission line connected with the fourth data line on the base substrate overlap with each other.

The design of the seventh data line 113 connected with the blue sub pixel B and the eighth data line 113 connected with the green sub pixel G can refer to the related designs of the third data line 113 and the fourth data line 113, which will not be repeated herein.

For example, FIG. 13 is a schematic plan view of a test unit in a display substrate provided by at least one embodiment of the present disclosure. As illustrated by FIG. 13, in the test cell, a plurality of first signal transmission lines 129 connected with the first color sub pixels 112A and a plurality of second signal transmission lines 130 connected with the second color sub pixels 112B are alternately arranged in sequence in the second direction Y. The first color sub pixels are green sub pixels G, and the second color sub pixels are blue sub pixels B or red sub pixels R. There are a plurality of thin film transistors in the test unit, each of the plurality of thin film transistors includes an active layer, a gate electrode, a source electrode and a drain electrode, and the thin film transistors are test switching transistors.

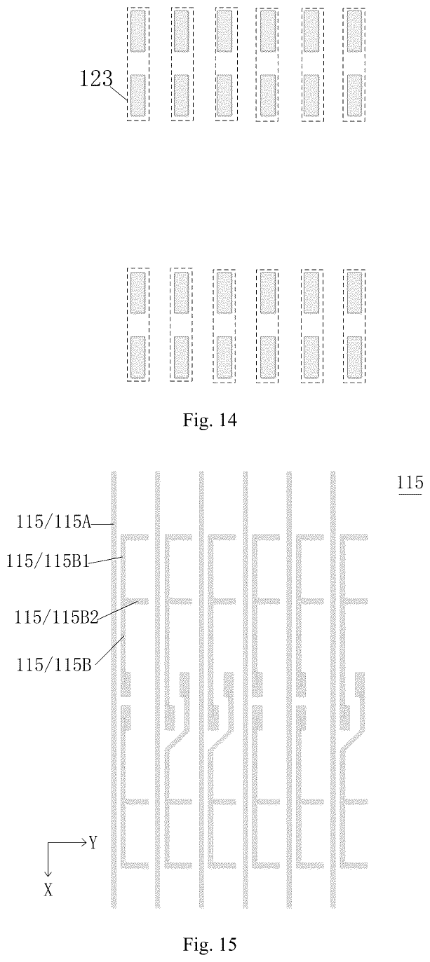

For example, FIG. 14 is a schematic plan view of an active layer in FIG. 13. As illustrated by combination with FIG. 14, the material of the active layer 123 is polysilicon. In FIG. 14, the structure of 12 complete active layers is shown, and each rectangular dashed box shows a complete active layer 123, that is, the 12 complete active layers 123 correspond to two repeating units. The six active layers 123 arranged in the first row are the active layers of the test switching transistors corresponding to three blue sub pixels B and three red sub pixels R arranged in the first row, and the six active layers 123 arranged in the second row are the active layers 123 of the test switching transistors corresponding to three blue sub pixels B and three red sub pixels R arranged in the second row, and only the six active layers 123 in the first row are described as a repeating unit.

For example, FIG. 15 is a schematic plan view of a first metal layer in FIG. 13. As illustrated by combination with FIG. 13, FIG. 15 and FIG. 3, the first metal layer 115 includes a first part 115A connected with the first color sub pixel and a second part 115B used as the gate electrode of the test switching transistor. The first color sub pixel 112A and the second color sub pixel 112B are not shown in FIG. 13 and FIG. 15, but they can be referred to 112A and 112B in FIG. 3. The second color sub pixel 112B includes a blue sub pixel B and a red sub pixel R. In the test stage, the test switching transistor is mainly used to control the blue sub pixel B and the red sub pixel R not to be turned on at the same time, even if only one of the blue sub pixel B and the red sub pixel R is turned on and the other is turned off at different times, so as to avoid the problem of color mixing when emitting light, which leads to the phenomenon of color deviation due to the low purity of the emitted light.

It should be noted that, the first part 115A in FIG. 15 is also the first signal transmission line 129 in FIG. 13.

For example, in combination with FIG. 13 and FIG. 15, the second part 115B of the first metal layer 115 includes a main body 15b1 and a branch part 15b2. The main body 115B1 is used to connect a first conductive layer first sub-part 118C of the first conductive layer 118, and the branch part 115B2 is used as a gate electrode of the test switching transistor, the first conductive layer first sub-part 118C provides a gate signal voltage for the test switching transistor. When describing the first conductive layer 118, the structure in the first conductive layer 118 will be described in detail.

For example, in combination with FIG. 13 and FIG. 15, the arrangement order of the sub pixels connected with the first signal transmission lines 129 and the second signal transmission lines 130 located in the first row is green sub pixel G, red sub pixel R, green sub pixel G, blue sub pixel B, green sub pixel G, blue sub pixel B, green sub pixel G, red sub pixel R, green sub pixel G, red sub pixel R, green sub pixel G and blue sub pixel B. The arrangement order of the sub pixels connected with the first signal transmission lines 129 and the second signal transmission lines 130 located in the first row is the same as the arrangement order of the sub pixels connected with the first signal transmission lines 129 and the second signal transmission lines 130 in other regions of the fanout region 104 except the connection region 114 in FIG. 3.

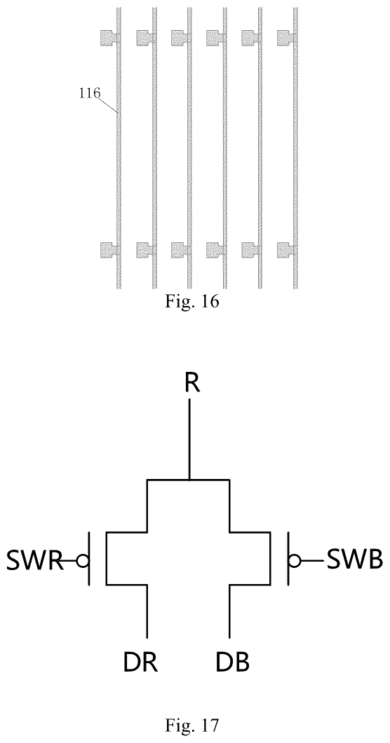

For example, FIG. 16 is a schematic plan view of a second metal layer in FIG. 13. Combined with FIG. 13 and FIG. 16, the transistor finally transmits the test signal to the second metal layer 116. Because the first signal transmission line 129 connected with the first color sub pixel 112A and the second signal transmission line 130 connected with the second color sub pixel 112B are located in different metal layers, the transistor can control the illumination of the first color sub pixel 112A and the second color sub pixel 112B respectively.

It should be noted that, the second signal transmission line 130 in FIG. 13 is located in the second metal layer 116 shown in FIG. 16, and the strip shown in FIG. 16 corresponds to the second signal transmission line 130 shown in FIG. 13.

It should be noted that, although the blue sub pixel B located in the first row and the red sub pixel R located in the second row are connected with a same second signal transmission line, or although the red sub pixel B located in the first row and the blue sub pixel B located in the second row are connected with the same second signal transmission line, the problem of signal crosstalk will not occur due to the control of the test switching transistor.

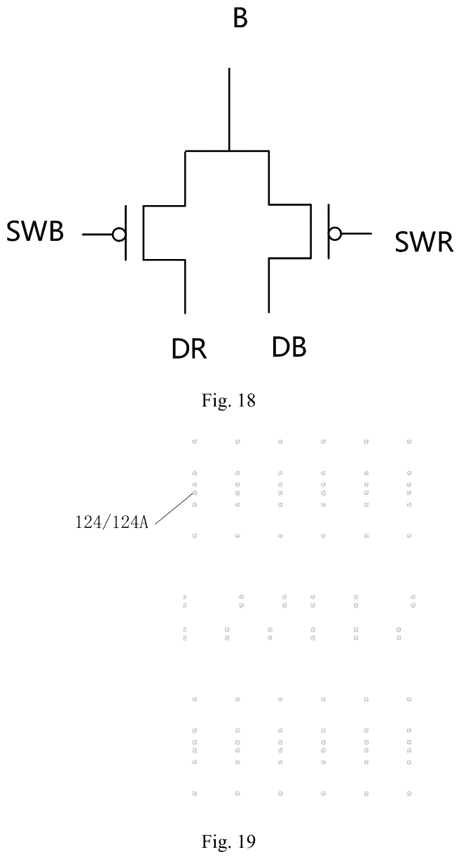

For example, FIG. 17 is a circuit diagram upon a first test switching transistor corresponding to a red sub pixel in FIG. 13 being turned on, and FIG. 18 is a circuit diagram upon a second test switching transistor corresponding to a blue sub pixel in FIG. 13 being turned on. As illustrated by FIG. 17 and FIG. 18, when testing the red monochrome picture, it is required that the red sub pixel is lit and the blue sub pixel is not lit; similarly, when testing a blue monochrome picture, it is required that the blue sub pixel is lit and the red sub pixel is not lit. For example, in one example, the input signal voltages are as follows: red sub pixel switching signal (SWR): −7V, blue sub pixel switching signal (SWB): +7V, red sub pixel source signal (DR): 3V, and blue sub pixel source signal (DB): 7V. For the first test switching transistor corresponding to the red sub pixel, when the SWR signal of −7V is applied to it, the first test switching transistor corresponding to the red sub pixel is turned on, and the DR signal of 3V is input into the second signal transmission line; at this time, when the applied SWB voltage is +7V, the second test switching transistor corresponding to the blue sub pixel is turned off, and the DB signal cannot be input to the second signal transmission line, so the voltage on the second signal transmission line is 3V, and the red sub pixel is lit at this time. For example, in another example, for the blue sub pixel, the second test switching transistor of the blue sub pixel is turned on when the SWB signal of −7V is applied to the second test switching transistor corresponding to the blue sub pixel, and the DB signal of 7V is input to the second signal transmission line; at this time, when the SWR voltage is +7V, the first test switching transistor corresponding to the red sub pixel is turned off, and the DR signal cannot be input to the second signal transmission line, so the voltage on the second signal transmission line is 7V, and the corresponding blue sub pixel is lit.

For example, FIG. 19 is a schematic view of a position of a third via hole structure of an interlayer insulating layer in FIG. 13, which is arranged at a side of a second metal layer away from the active layer. As illustrated by FIG. 19, there are a plurality of third via hole structures 124A in the interlayer insulating layer 124, the first conductive layer and other structures at a side of the second metal layer 116 away from the active layer can be electrically connected with the first metal layer 115, the second metal layer 116 and the active layer through the plurality of third via hole structures 124A.

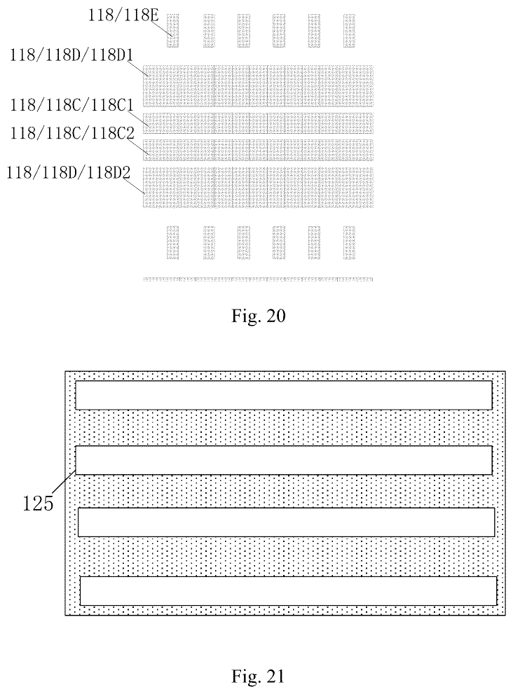

For example, FIG. 20 is a schematic plan view of a first conductive layer in FIG. 13. As illustrated by combination with FIG. 13, FIG. 15 and FIG. 20, the first conductive layer 118 includes a first conductive layer first sub-part 118C1, a first conductive layer second sub-part 118D1 and a first conductive layer third sub-part 118E. The first conductive layer first sub-part 118C1 is electrically connected with a main body 115B1 included in a second part 115b of the first metal layer 115 to provide a gate driving signal for the test switching transistor. The source electrode S1 of the first test switching transistor controlling the red sub pixel R is electrically connected with the first conductive layer second sub-part 118D1, and is electrically connected with the first test signal input terminal through the first conductive layer second sub-part 118D1, thereby providing a monochromatic power supply voltage test signal for the red sub pixel R. The drain electrode DI of the first test switching transistor for controlling the red sub pixel R is electrically connected with the second signal transmission line 130, and the source electrode S1 and the drain electrode D1 are overlapped on two sides of the active layer of the first test switching transistor corresponding to the red sub pixel, and the second part 115B of the first metal layer 115 includes a branch part 112b2 serving as the gate electrode of the first test switching transistor for controlling the red sub pixel R. The first conductive layer third sub-part 118E is configured to be electrically connected with the second signal transmission line 130.

For example, as illustrated by FIG. 13, FIG. 15 and FIG. 20, the first conductive layer 118 further includes a first conductive layer first sub-part 118C2 and a first conductive layer second sub-part 118D2. The first conductive layer first sub-part 118C2 is electrically connected with the main body 115B1 included in the second part 115b of the first metal layer 115 to provide a gate driving signal for the test switching transistor. The source electrode S1 of the second test switching transistor controlling the blue sub pixel B is electrically connected with the first conductive layer second sub-part 118D2, and is electrically connected with the second test signal input terminal through the first conductive layer second sub-part 118D2, thereby providing a monochromatic power supply voltage test signal for the blue sub pixel B. The drain electrode D1 of the second test switching transistor for controlling the blue sub pixel B is electrically connected with the second signal transmission line 130, and the source electrode S1 and the drain electrode D1 are overlapped on two sides of the active layer of the second test switching transistor corresponding to the blue sub pixel B, and the second part 115B of the first metal layer 115 includes a branch part 112b2 serving as the gate electrode of the second test switching transistor for controlling the blue sub pixel.

For example, in combination with FIG. 13, FIG. 15 and FIG. 20, in a repeating unit, the first conductive layer 118 includes two parallel first conductive layer first sub-parts 118C. For example, the first conductive layer first sub-part 118C on the upper side is connected with the gate electrode of the first test switching transistor that controls the red sub pixel to be lit, and the first conductive layer first sub-part 118C on the lower side is connected with the gate electrode of the second test switching transistor that controls the blue sub pixel to be lit, so that the gate driving voltage can be applied to the first test switching transistor that controls the red sub pixel to be lit and the second test switching transistor that controls the blue sub pixel to be lit respectively, so that the blue sub pixel and the red sub pixel are illuminated at different stages, so as to avoid color mixing of the red light and the blue light.

For example, FIG. 21 is a schematic plan view of a third planarization layer in FIG. 13. Combining with FIG. 13, FIG. 15 and FIG. 21, the third planarization layer 125 is provided with a plurality of grooves which can realize the electrical connection between the first conductive layer 118 and the second conductive layer 120 above the first conductive layer 118.

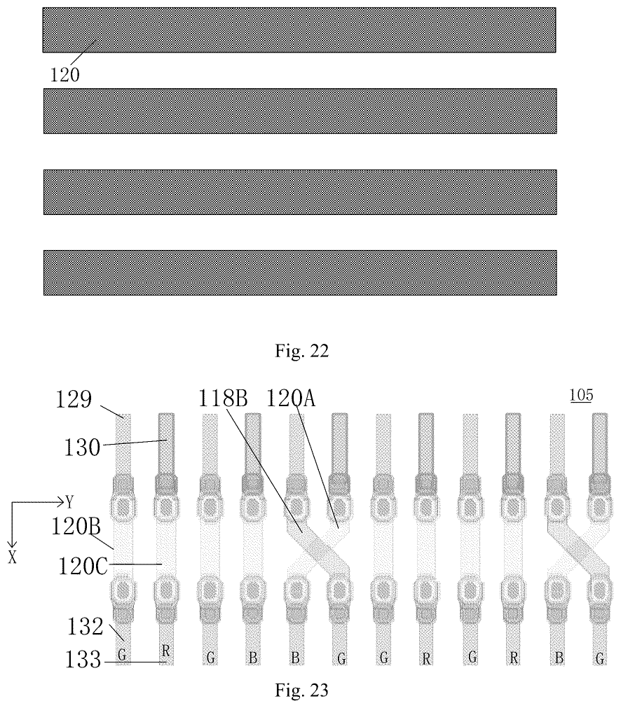

For example, FIG. 22 is a schematic plan view of a second conductive layer in FIG. 13. Combining with FIG. 13 and FIG. 22, the planar shape of the second conductive layer 120 is the same as the planar shape of the first conductive layer second sub-part 118D of the first conductive layer 118, and an orthographic projection of the second conductive layer 120 on the base substrate 111 overlaps with an orthographic projection of the first conductive layer second sub-part 118D of the first conductive layer 118 on the base substrate 111.

For example, FIG. 23 is a schematic plan view of a junction of a pad region and a test unit in a display substrate provided by at least one embodiment of the present disclosure. As illustrated by FIG. 23, in the pad region 105, a plurality of third signal transmission lines 132 connected with first color sub pixels and a plurality of fourth signal transmission lines 133 connected with second color sub pixel are arranged in sequence in the second direction Y. The first color sub pixel is a green sub pixel G and the second color sub pixel includes a blue sub pixel B or a red sub pixel R. In the pad region 105, a plurality of third signal transmission lines 132 and a plurality of fourth signal transmission lines 133 are arranged in the second direction Y. The arrangement order of the sub pixels connected with the plurality of third signal transmission lines 132 and the plurality of fourth signal transmission lines 133 is the same as the arrangement order of sub pixels connected with the plurality of data lines 113 and the plurality of data connection lines 128, and a part of the plurality of third signal transmission lines 132 are in odd-numbered columns, the other part of the plurality of third signal transmission lines 132 are in even-numbered columns, a part of the plurality of fourth signal transmission lines 133 are in odd-numbered columns, and the other part of the plurality of fourth signal transmission lines 133 are in an even-numbered column.

For example, in combination with FIG. 4 and FIG. 23, at least one third signal transmission line 132 and the second data line 113B correspond to the same color sub pixel, for example, both correspond to the green sub pixel. At least one fourth signal transmission line 133 and the first data line 113A correspond to the sub pixels of the same color, for example, both correspond to the red sub pixels.

For example, in FIG. 23, the sub pixels connected with the plurality of third signal transmission lines 132 and the plurality of fourth signal transmission lines 133 are green sub pixel G, red sub pixel R, green sub pixel G, blue sub pixel B, blue sub pixel B, green sub pixel G, green sub pixel G, red sub pixel R, green sub pixel G, red sub pixel R, blue sub pixel B and green sub pixel G in order, so as to be the same as the arrangement order of the data lines 113 and the data connection lines 128 at the junction of the display region 101 and the fanout region 104 in FIG. 3.

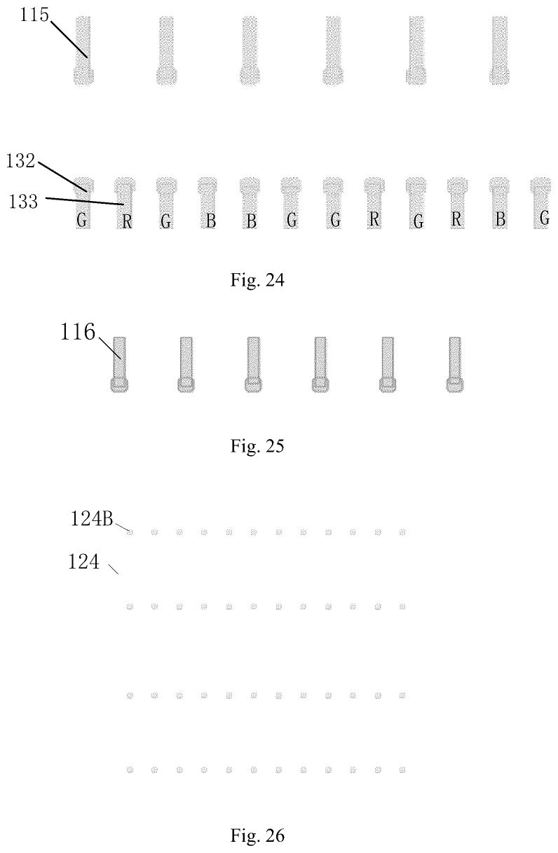

For example, FIG. 24 is a schematic plan view of a first metal layer in FIG. 23. As illustrated by FIG. 24, the first metal layer 115 includes a plurality of mutually spaced parts in a first row, and the plurality of parts in the first row correspond to the first signal transmission lines 129 connected with the first color sub pixels in the test unit. A plurality of parts in the second row correspond to the third signal transmission lines 132 connected with the first color sub pixels and the fourth signal transmission lines 133 connected with the second color sub pixels in the pad region 105, that is, the third signal transmission lines 132 connected with the first color sub pixels and the fourth signal transmission lines 133 connected with the second color sub pixels in the pad region 105 are arranged in the same layer. In FIG. 24, the third signal transmission line 132 and the fourth signal transmission line 133 from left to right receive the driving signals of the green sub pixel G, the red sub pixel R, the green sub pixel G, the blue sub pixel B, the blue sub pixel B, the green sub pixel G, the green sub pixel G, the red sub pixel R, the green sub pixel G, the red sub pixel R, the blue sub pixel B and the green sub pixel G in order to drive the corresponding color sub pixel to be lit.

For example, FIG. 25 is a schematic plan view of a second metal layer in FIG. 23. As illustrated by combination with FIG. 23 and FIG. 25, the second metal layer 116 includes a plurality of mutually spaced parts, and the mutually spaced parts included in the second metal layer 116 are respectively inserted at the spaced positions of the mutually spaced parts included in the first metal layer 115 in FIG. 24.

For example, FIG. 26 is a schematic view of a position of a fourth via hole structure of an interlayer insulating layer arranged at a side of a second metal layer away from an active layer in FIG. 23. As illustrated by FIG. 26, a plurality of fourth via hole structures 124B are arranged in the interlayer insulating layer 124, and the first conductive layer or other layer structures arranged in the second metal layer 116 can be electrically connected with the first metal layer 115 and the second metal layer 116 through the plurality of fourth via hole structures 124B.

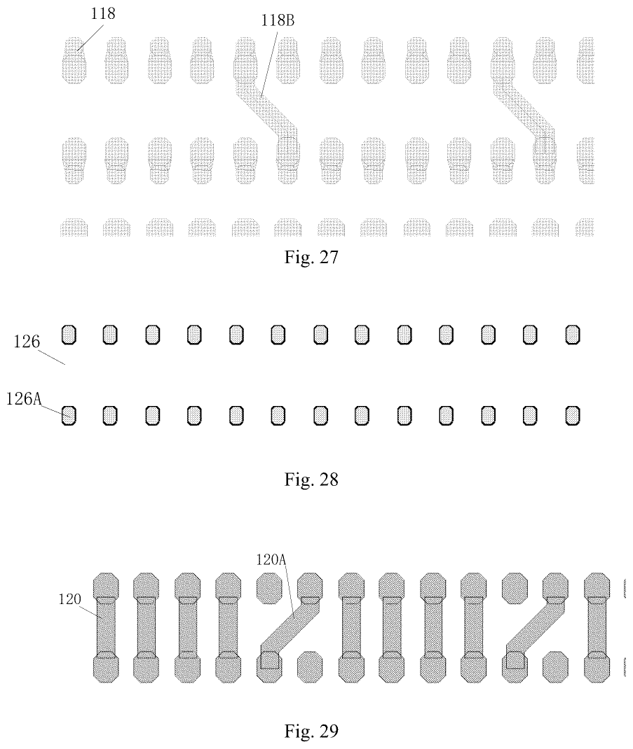

For example, FIG. 27 is a schematic plan view of a first conductive layer in FIG. 23. As illustrated by FIG. 27, the first conductive layer 118 includes a first transfer line 118B extending from the upper left corner to the lower right corner. The third signal transmission line 132 arranged in an even number column and the corresponding first signal transmission line 129 are electrically connected through the first transfer line 118B.

For example, FIG. 28 is a schematic plan view of a fourth planarization layer in FIG. 23. As illustrated by FIG. 28, the fourth planarized layer 126 is provided with a plurality of fifth via hole structures 126A, which are used to connect the first conductive layer 118 with other conductive layer structures thereon.

For example, FIG. 29 is a schematic plan view of a second conductive layer in FIG. 23. As illustrated by FIG. 29, the second conductive layer 120 includes a second transfer line 120A extending from the upper right corner to the lower left corner. The fourth signal transmission line 133 arranged in an odd-numbered column and the corresponding second signal transmission line 130 are electrically connected by the second transfer line 120A, the first transfer line 118B is in the first conductive layer 118 and the second transfer line 120A is in the second conductive layer 120, and the first transfer line 118B and the second transfer line 120A are located in different layers. The fourth signal transmission line 133 arranged in an even-numbered column is electrically connected with a corresponding second signal transmission lines through a fourth transfer line 120C, and the third signal transmission line arranged in an odd-numbered column is electrically connected with a corresponding first signal transmission line through a third transfer line 120B, both the third transfer line 120B and the fourth transfer line 120C are arranged in the second conductive layer 120.

For example, in combination with FIG. 23, FIG. 27 and FIG. 29, the at least one third signal transmission line 132 arranged in an even-numbered column and a fourth signal transmission line 133 arranged in an odd-numbered column are arranged adjacent to each other, and on a plane parallel to the main surface of the base substrate 111, the first transfer line 118B connected with the at least one third signal transmission line 132 arranged in an even-numbered column crosses with the second transfer line 120A connected with the fourth signal transmission line 133 arranged in the odd-numbered column. The third signal transmission line 132 arranged in the even-numbered columns is electrically connected with the first signal transmission line 129 through the first transfer line 118B, and the fourth signal transmission line 133 arranged in the odd-numbered column is electrically connected with the second signal transmission line 130 through the second transfer line 120A, the first transfer line 110B and the second transfer line 120A are located in different layers, the first transfer line 118B is in the first conductive layer and the second transfer line 120A is in the second conductive layer.

For example, in combination with FIG. 23, FIG. 27 and FIG. 29, the third signal transmission line 132 arranged in the odd-numbered column is electrically connected with a corresponding first signal transmission lines 129 through the third transfer line 120B, and the fourth signal transmission line 133 arranged in the even-numbered column is electrically connected with a corresponding second signal transmission lines 130 through the fourth transfer line 120C, both the third transfer line 120B and the fourth transfer line 120C are arranged in the second conductive layer 120.

For example, in other examples, at least one third signal transmission line 132 arranged in the odd-numbered column and one fourth signal transmission line 133 arranged in the even-numbered column may be arranged adjacent to each other, and on a plane parallel to the main surface of the base substrate, the third transfer line 120B connected with the at least one third signal transmission line 132 arranged in the odd-numbered column and the fourth transfer line 120C connected with one fourth signal transmission line 133 arranged in the even-numbered column may cross with each other.

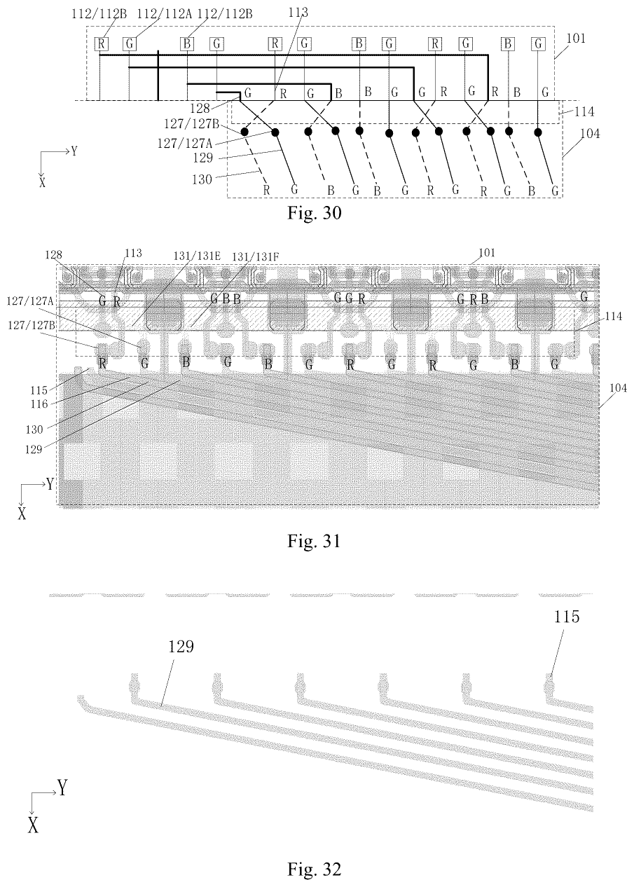

For example, FIG. 30 is a schematic diagram of an arrangement of data lines, data connection lines and signal transmission lines in a display region and a fanout region in another display substrate provided by at least one embodiment of the present disclosure, and FIG. 31 is a layout diagram of the display region and the fanout region of a display substrate provided by at least one embodiment of the present disclosure. For example, with reference to FIG. 2, FIG. 30, and FIG. 31, the display substrate 100 includes: a base substrate 111, which includes a display region 101 and a peripheral region 110 surrounding the display region 101. The peripheral region 110 includes a fanout region 104 adjacent to the display region 101 and a pad region 105 at a side of the fanout region 104 away from the display region 101. The display region 101 is provided with a plurality of sub pixels 112 arranged in a matrix, and the plurality of sub pixels 112 are arranged to form a plurality of columns of sub pixels, and the plurality of columns of sub pixels 112 are electrically connected with a plurality of data lines 113 in one-to-one correspondence, that is, each column of sub pixels 112 is connected with a data line 113. The fanout region 104 includes a connection region 114 adjacent to the display region 101. A part of the data lines 113 are directly connected with the connection pads 127 located in the connection region 114, and the other part of the data lines 113 are connected with the connection pads 127 located in the connection region 114 through the data connection lines 128. The plurality of sub pixels 112 include a plurality of columns of first color sub pixels 112A and a plurality of columns of second color sub pixels 112B, and the connection pads 127 include a plurality of first connection pads 127A and a plurality of second connection pads 127B, the plurality of first connection pads 127A are electrically connected with the plurality of columns of the first color sub pixels 112A and the plurality of second connection pads 127B are electrically connected with the plurality of columns of the second color sub pixels 112B. There are a plurality of first signal transmission lines 129 and a plurality of second signal transmission lines 130 arranged at intervals in positions of the fanout region 104 close to the pad region 105, the first signal transmission lines 129 are arranged in the first metal layer 115 and the second signal transmission lines 130 are arranged in the second metal layer 116 which is different from the first metal layer 115; the plurality of first signal transmission lines 129 and the plurality of first connection pads 127A are electrically connected in one-to-one correspondence, and the plurality of second signal transmission lines 130 and the plurality of second connection pads 127B are electrically connected in one-to-one correspondence, so that two adjacent data connection lines 128 and at least two data lines 113 located between two adjacent data connection lines 128 form a data line group 13. The connection pads 127 respectively connected with the data lines 113 and the data connection lines 128 in a data line group 13 include one first connection pad 127A and one second connection pad 127B, and in at least one data line group 13, the data connection lines 128 are electrically connected with the first connection pad 127A or the second connection pad 127B through a connection electrode 131, and an orthographic projection of the connection electrode 131 on the base substrate 111 and a data line 113 adjacent to the data connection line 128 that is connected to the connection electrode 131 on the base substrate have an overlapping part.

For example, as illustrated by FIG. 2, FIG. 30 and FIG. 31, a plurality of data lines 113 and a plurality of data connection lines 128 are arranged on the base substrate 111, extend in the first direction X in the display region 101 and are arranged in the second direction Y intersecting with the first direction X. The plurality of data lines 113 and the plurality of data connection lines 128 extend from the display region 101 to the fanout region 104. At the positions of the display region 101 close to the fanout region 104, a part of the plurality of data lines 113 is arranged in the odd-numbered columns, the other part of the plurality of data lines 113 is arranged in the even-numbered columns, and a part of the plurality of data connection lines 128 is arranged in the even-numbered columns and the other part of the plurality of data connection lines 128 is arranged in the odd-numbered columns. The fanout region 104 includes a connection region 114 adjacent to the display region 101. In other regions of the fanout region 104 except the connection region 114, a plurality of first signal transmission lines 129 and a plurality of second signal transmission lines 130 are arranged in the second direction Y, and one kind of the first signal transmission lines 129 and the second signal transmission lines 130 is arranged in odd-numbered columns, the other kind of the plurality of first signal transmission lines 129 and the plurality of second signal transmission lines 130 are arranged in the even number columns, the plurality of first signal transmission lines 129 are arranged in the first metal layer 115, and the plurality of second signal transmission lines 130 are arranged in the second metal layer 116 which is located in a different layer from the first metal layer 115. This design can make the arrangement order of the sub pixels connected with the data lines 113 and the data connection lines 128 at the positions of the display region 101 close to the fanout region 104 different from the arrangement order of the sub pixels connected with the first signal transmission lines 129 and the second signal transmission lines 130 at the positions of the fanout region away from the display region 101, so as to adjust the plurality of first signal transmission lines 129 or the plurality of second signal transmission lines 130 connected with the sub pixels of the same color to be located in the same film layer, so as to avoid different parasitic capacitances caused by different film layers of the first signal transmission lines 129 or the second signal transmission lines 130 connected with the sub pixels of the same color, and further avoid the problem that different loads of the first signal transmission lines 129 or the second signal transmission lines 130 connected with the sub pixels of the same color cause different data signal writing amounts.

For example, in one example, the first color sub pixel 112A is a green sub pixel G, and the second color sub pixel 112B includes a red sub pixel R and a blue sub pixel B. For example, as illustrated by FIG. 30, the data line 113 and the data connection line 128 are sequentially arranged as a whole at the position of the display region 101 close to the fanout region 104 along the first direction X, and along the second direction Y, a data connection line 128 (first data connection line) connected with the green sub pixel G, a data line 113 (first data line) connected with the red sub pixel R, a data line 113 (second data line) connected with the green sub pixel G, a data connection line 128 (second data connection line) connected with the blue sub pixel B, a data line 113 (third data line) connected with the blue sub pixel B, a data line 113 (fourth data line) connected with the green sub pixel G, a data connection line 128 (third data connection line) connected with the green sub pixel G, a data line 113 (fifth data line) connected with the red sub pixel R, a data line 113 (sixth data line) connected with the green sub pixel G, a data connection line 128 (fourth data connection line) connected with the red sub pixel R and a data line 113 (seventh data line) connected with the blue sub pixel B, and a data line 128 (eighth data line) connected with the green sub pixel G are arranged in sequence. That is, in this example, the first data connection line, the second data line, the third data line, the third data connection line, the sixth data line and the seventh data line are arranged in the odd-numbered columns, and the first data line, the second data connection line, the fourth data line, the fifth data line, the fourth data connection line and the eighth data line are arranged in the even-numbered columns.

For example, in FIG. 30, in other regions of the fanout region 104 except the connection region 114, among the plurality of first signal transmission lines 129 and the plurality of second signal transmission lines 130 connected with the sub pixels in FIG. 30, the first signal transmission lines 129 are arranged in the even-numbered columns and the second signal transmission lines 130 are arranged in the odd-numbered columns, and the first signal transmission lines 129 and the first connection pads 127A are electrically connected in one-to-one correspondence, and are all electrically connected with the plurality of first color sub pixels 112A in one-to-one correspondence; the plurality of second signal transmission lines 130 are electrically connected with a plurality of second connection pads 127B in one-to-one correspondence, and are all electrically connected with a plurality of second color sub pixels 112B in one-to-one correspondence, so that the plurality of first signal transmission lines 129 are arranged in the first metal layer, and the plurality of second signal transmission lines 130 are arranged in the second metal layer which is different from the first metal layer. That is, the display substrate performs a jumper design on the data lines and the data connection lines at the connection region of the fanout region adjacent to the display region (AA), and the arrangement order of the sub pixels connected with the data lines and the data connection lines at the positions of the display region close to the fanout region is different from the arrangement order of the sub pixels connected with the plurality of first signal transmission lines and the plurality of second signal transmission lines at the positions of the fanout region away from the display region, so as to adjust the plurality of first signal transmission lines or the plurality of second signal transmission lines connected with the sub pixels of the same color to be located in the same film layer, so as to avoid different parasitic capacitances caused by a plurality of first signal transmission lines or a plurality of second signal transmission lines connected with the sub pixels of the same color in different film layers, and further avoid the problem that different loads of the first signal transmission lines 129 or the second signal transmission lines 130 connected with the sub pixels of the same color cause different data signal writing amounts.

It should be noted that, the first data line to the eighth data line refer to an order sorting the data lines located in the same row as the data connection lines, and the first data connection line to the fourth data connection line refers to an order sorting the data connection lines inserted in FIP mode in sequence. The first data line to the eighth data line and the first data connection line to the fourth data connection line are taken from the data lines and the data connection lines, respectively, only for the convenience of description, and do not refer to other data lines except the data lines and the data connection lines.

It should also be noted that, the jumper design on the data lines and the data connection lines mentioned above refers to exchanging the positions of adjacent data lines and data connection lines, and still maintaining the adjacent positional relationship, which can be realized by crossing the data line and data connection line located in different layers at the positions corresponding to the connection region on the plane.

For example, as illustrated by FIG. 31, in other regions of the fanout region 104 except the connection region 114, 12 signal transmission lines arranged in sequence along the second direction Y are described as a cycle, and the 12 signal transmission lines in one cycle include a plurality of first signal transmission lines 129 and a plurality of second signal transmission lines 130. In FIG. 31, the plurality of first signal transmission lines 129 are all arranged in even-numbered columns, and the plurality of second signal transmission lines 130 are arranged in odd-numbered columns.

For example, as illustrated by FIG. 31, in the fanout region 104, the second connection pad 127B connected with the red sub pixel R, the first connection pad 127A connected with the green sub pixel G, the second connection pad 127B connected with the blue sub pixel B, the first connection pad 127A connected with the green sub pixel G, the second connection pad 127B connected with the blue sub pixel B, and the first connection pad 127A connected with the green sub pixel G, the second connection pad 127B connected with red sub pixel R, the first connection pad 127A connected with the green sub pixel G, the second connection pad 127B connected with red sub pixel R, the first connection pad 127A connected with the green sub pixel G, the second connection pad 127B connected with the blue sub pixel B, and the first connection pad 127A connected with the green sub pixel G are sequentially arranged along the second direction Y, a plurality of the first connection pads 127A and a plurality of the first signal transmission lines 129 are electrically connected in one-to-one correspondence, and a plurality of second connection pads 127B and a plurality of second signal transmission lines 130 are electrically connected in one-to-one correspondence, so that the plurality of first signal transmission lines 129 can be arranged in the first metal layer 115, and the plurality of second signal transmission lines 130 can be arranged in the second metal layer 116 which is located in a different layer from the first metal layer 115. In this way, signal transmission lines connected with the sub pixels of the same color can be adjusted to be located in the same film layer, so as to avoid different parasitic capacitances caused by different film layers of signal transmission lines connected with sub pixels of the same color, and further avoid the problem that different loads of signal transmission lines connected with the sub pixels of the same color cause different data signal writing amounts.

For example, in combination with FIG. 2 and FIG. 31, the display region 101 may include a plurality of thin film transistors, which are test switching transistors, and at least one of the plurality of thin film transistors may have a double-gate structure. For example, the first thin film transistor includes a first gate electrode and a second gate electrode, and all other thin film transistors have only one gate electrode. The first metal layer 115 may be formed in the same layer as the first gate electrode of the first thin film transistor, and the second metal layer 116 may be formed in the same layer as the second gate electrode of the first thin film transistor. In a direction perpendicular to a main surface of the base substrate 111, although not shown in FIG. 31, there is also an insulating layer between the first metal layer 115 and the second metal layer 116, which can prevent electrical communication between the first signal transmission line 129 and the second signal transmission line 130 having an overlapping part on the plane parallel to the main surface of the base substrate 111.

For example, when the parasitic capacitances of the first metal layer 115 and the second metal layer 116 change, the resistances of the first signal transmission lines 129 connected with the green sub pixels G will be different, which will lead to the difference in display brightness. Therefore, in the embodiment of the present disclosure, in the connection region 114, a jumper design is performed on the first data connection line 128 connected with the green sub pixel G and the first data line 113 connected with the red sub pixel R, on the second data line 113 connected with the green sub pixel G and the second data connection line 128 connected with the blue sub pixel B, and on the third data connection line 128 connected with the green sub pixel G and the fifth data line 113 connected with the red sub pixel R, and on the sixth data line 113 connected with the green sub pixel G and the fourth data connection line 128 connected with the red sub pixel R, so that the green sub pixels G are still connected with the first metal layer 115, and the blue sub pixel B and the red sub pixel R are still connected with the second metal layer 116. After connection, in other regions of the fanout region 104 except the connection region 114, the arrangement order of the sub pixels connected with the first signal transmission line 129 and the second signal transmission line 130 is RGBGBG RGRGBG, so that the first signal transmission lines 129 connected with the green sub pixel G are arranged at even-numbered positions (the first signal transmission lines 129 and the second signal transmission lines 130 connected with the sub pixels in FIG. 31 are sorted as a whole) and located in the first metal layer 115, and the second signal transmission lines 130 connected with the blue sub pixel B or the red sub pixel R are arranged at odd-numbered positions (the first signal transmission lines 129 and the second signal transmission lines 130 connected with the sub pixel in FIG. 31 are sorted as a whole) and located at the second metal layer 116, so that the influence caused by parasitic capacitance can be avoided.

For example, FIG. 32 is a schematic diagram corresponding to the plane structure of the first metal layer in FIG. 31. As illustrated by combination with FIG. 31 and FIG. 32, in other regions of the fanout region 104 except the connection region 114, a plurality of first signal transmission lines 129 in the first metal layer 115 all have the shape of a folded line, and each of the first signal transmission lines 129 includes a vertical part extending along the first direction X, and then an oblique part extending along a direction at an obtuse angle to the first direction X, and the oblique part will eventually make the first signal transmission line 129 shrink inward to the middle region. The vertical portions of the plurality of first signal transmission lines 129 are uniformly distributed in the second direction Y, so that signals transmitted to the first signal transmission lines 129 are more uniform.

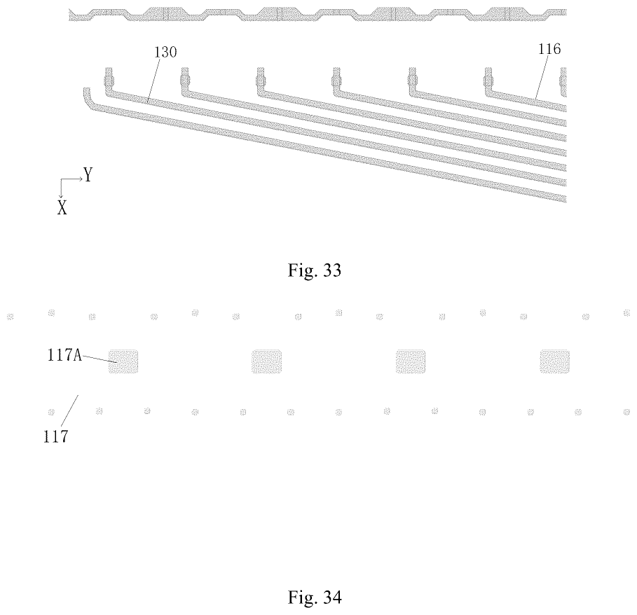

For example, FIG. 33 is a schematic diagram of the plane structure corresponding to the second metal layer in FIG. 31 provided by at least one embodiment of the present disclosure. Combining with FIG. 31 and FIG. 33, in other regions of the fanout region 104 except the jumper position, a plurality of second signal transmission lines 130 in the second metal layer 116 have the shape of a folded line and each of the plurality of second signal transmission lines 130 includes a vertical part extending along the first direction X, and then an oblique line extending along a direction at an obtuse angle to the first direction X, and the oblique part will eventually make the second signal transmission line 130 shrink inward to the middle region. The vertical portions of the plurality of second signal transmission lines 130 are uniformly distributed in the second direction Y, so that signals transmitted to the second signal transmission lines 130 are more uniform.

For example, FIG. 34 is a schematic plan view of the interlayer insulating layer arranged at a side of the second metal layer away from the base substrate in FIG. 31. As illustrated by FIG. 34, the interlayer insulating layer 117 is provided with a plurality of first hole structures 117A, and the plurality of first hole structures 117A can realize the electrical connection between the structure arranged at a side of the interlayer insulating layer 117 away from the base substrate 111 and the structure of the interlayer insulating layer 117 close to the base substrate 111.

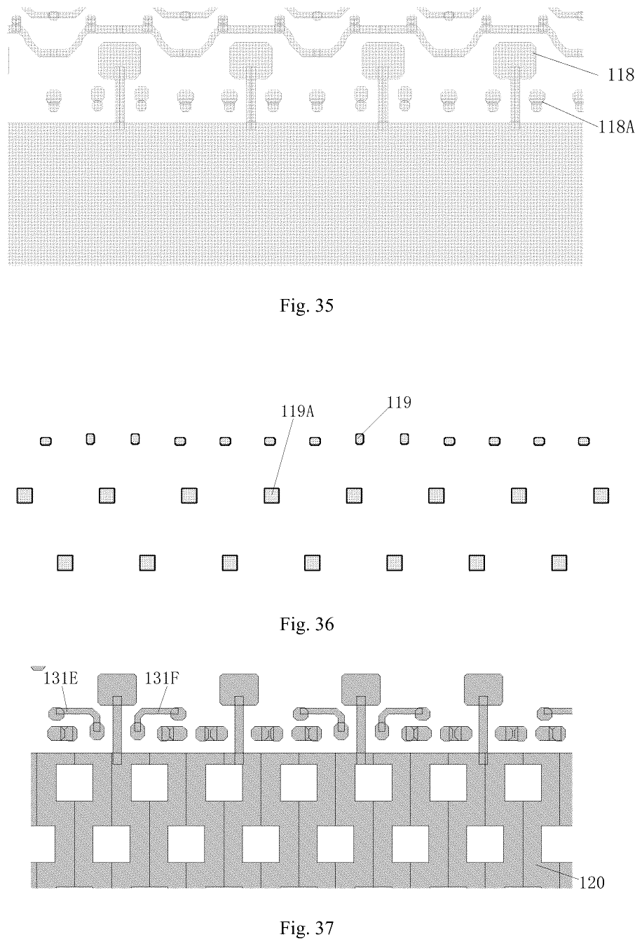

For example, FIG. 35 is a schematic diagram of the plane structure corresponding to the first conductive layer in FIG. 31. As illustrated by FIG. 35, the connection pads 127 include a double-layer structure, and a plurality of first connectors 118A included in the first conductive layer 118 can be used as a layer structure of the connection pads 127 close to the base substrate 111, and cooperate with the second connectors mentioned later to realize that a plurality of data lines 113 or a plurality of data connection lines 128 located in the display region 101 are connected with a plurality of corresponding first signal transmission lines 129 and a plurality of corresponding second signal transmission lines in the fanout region 104. The material of the first conductive layer 118 may be a conductive metal or a conductive metal oxide, as long as a stable connection relationship can be satisfied, which is not limited by the embodiment of the present disclosure.

For example, FIG. 36 is a schematic plan view of the first planarization layer at a side of the first conductive layer away from the base substrate in FIG. 31. As illustrated by FIG. 36, a plurality of second hole structures 119A are arranged in the first planarization layer 119, and the plurality of second hole structures 119A are used to connect the first conductive layer 118 and the second conductive layer at a side of the first planarization layer 119 away from the base substrate 111.

For example, FIG. 37 is a schematic plan view corresponding to the second conductive layer in FIG. 31. As illustrated by FIG. 37, the second conductive layer 120 includes a plurality of connection electrodes 131, which include a plurality of first connection electrodes 131E and a plurality of second connection electrodes 131F, and each first connection electrode 131E and each second connection electrode 131F have a bent structure. The plurality of first connection electrodes 131E are used to connect the data connection lines 128 in the third conductive layer mentioned later and the corresponding first signal transmission lines 129, and the plurality of second connection electrodes 131F are used to connect the data connection lines 128 in the third conductive layer and the corresponding second signal transmission lines 130. As illustrated by FIG. 37, the bent structure of the first connection electrode 131E and the second connection electrode 131F can realize the jumping of the first data connection line 128 connected with the green sub pixel G and the first data line 113 connected with the red sub pixel R, and the jumping of the second data line 113 connected with the green sub pixel G and the second data connection line 128 connected with the blue sub pixel B, the jumping of the third data connection line 128 connected with the green sub pixel G and the fifth the data line 113 connected with the red sub pixel R, and the jumping of the fourth data connection line 128 connected with the red sub pixel R and the sixth data line 113 connected with the green sub pixel G. It should be noted that the above jumping is to realize the exchange of arrangement positions of the first signal transmission line connected with the above-mentioned data connection line and the second signal transmission line connected with the above-mentioned data line in the second direction Y.

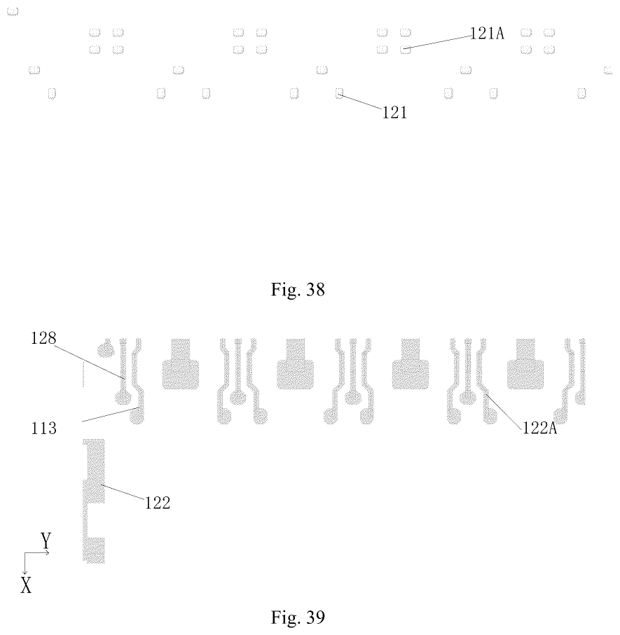

For example, FIG. 38 is a schematic plan view of the second planarization layer at a side of the second conductive layer away from the base substrate in FIG. 31. As illustrated by FIG. 38, a plurality of third hole structures 121A are arranged in the second planarization layer 121, and the plurality of third hole structures are used to connect the second conductive layer 120 and the third conductive layer at a side of the second planarization layer 121 away from the base substrate 111.

For example, FIG. 39 is a schematic diagram of the plane structure corresponding to the third conductive layer in FIG. 31. As illustrated by FIG. 39, the third conductive layer 122 has a plurality of data lines 113 and a plurality of data connection lines 128. It can be seen from FIG. 39, along the second direction Y, a plurality of data lines 113 and a plurality of data connection lines 128 are sorted, which are a first data connection line, a first data line, a second data line, a second data connection line, a third data line, a fourth data line, a third data connection line, a fifth data line, a sixth data line, a fourth data connection line, a seventh data line and an eighth data line in turn. That is, the first data connection line 128 refers to the data connection line arranged at the first position among the four data connection lines, that is, the first one of the data connection lines 128, and the second data connection line 128 to the fourth data connection line 128 have similar definitions; the first data line 113 refers to the data line arranged at the first position among the eight data lines, that is, the first one of the data lines 113, and the second data line 113 to the eighth data line 113 have similar definitions.

For example, as illustrated by FIG. 31 and FIG. 39, the first data connection line 128 extends linearly along the first direction X; the first data line 113 bends and extends along the first direction X, and the connection end faces a direction opposite to the second direction Y; the second data line 113 bends and extends along the first direction X, and the connection end faces the second direction Y; the second data connection line 128 extends linearly along the first direction X; the third data line 113 bends and extends in the first direction X, and the connection end faces the second direction Y; the fourth data line 113 bends and extends along the first direction X, and the connection end extends in the direction opposite to the second direction Y; the third data connection line 128, the fifth data line 113, the sixth data line 113, the fourth data connection line 128, the seventh data line 113 and the eighth data line 113 sequentially repeat the shapes of the first data connection line 128, the first data line 113, the second data line 113, the second data connection line 128, the third data connection line 113 and the fourth data connection line 113, and the details thereof are not repeated herein.

For example, in an example, as illustrated by FIG. 2, FIG. 31 and FIG. 39, the at least one data connection line 128 located in the odd-numbered column extends to a side close to the pad region 105 in the fanout region 104, and then is electrically connected with the corresponding first signal transmission line 129 through the first connection electrode 131E provided in the second conductive layer 120. The first data line 113 adjacent to the data connection line 128 crosses the first connection electrode 131E to be electrically connected with the corresponding second signal transmission line 130, that is, in FIG. 31, the first data line 113 connected with the red sub pixel R crosses the first connection electrode 131E connecting the first data connection line 128 connected with the green sub pixel G and the first signal transmission line 129. The second data line 113 connected with the green sub pixel G crosses the second connection electrode 131F connecting the second data connection line 128 connected with the blue sub pixel B and the second signal transmission line 130. The fifth data line 113 connected with the red sub pixel R crosses the first connection electrode 131E connecting the third data connection line 128 connected with the green sub pixel G and the first signal transmission line 129. The sixth data line 113 connected with the green sub pixel G crosses the second connection electrode 131F connecting the fourth data connection line 128 connected with the red sub pixel R and the second signal transmission line 130.

It should be noted that, the crossing of the data line across the first connection electrode and the crossing of the data line across the second connection electrode respectively refers to that the data line and the corresponding first connection electrode overlap on the plane parallel to the main surface of the base substrate, the data line and the corresponding second connection electrode overlap on the plane parallel to the main surface of the base substrate, that is, an orthographic projection of the data line on the base substrate and an orthographic projection of the corresponding first connection electrode overlap with each other, and an orthographic projection of the data line on the base substrate and an orthographic projection of the corresponding second connection electrode overlap with each other.

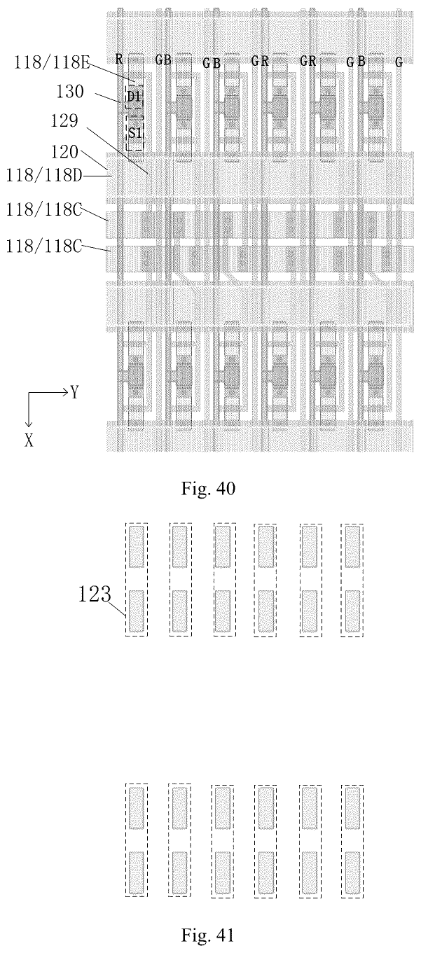

For example, FIG. 40 is a schematic diagram of the plane structure of a test cell in a display substrate provided by at least one embodiment of the present disclosure. As illustrated by FIG. 40, in the test cell, a plurality of first signal transmission lines 129 connected with the first color sub pixels 112A and a plurality of second signal transmission lines 130 connected with the second color sub pixels 112B are alternately arranged in sequence in the second direction Y. The first color sub pixel is a green sub pixel G, and the second color sub pixel is a blue sub pixel B or a red sub pixel R. There are a plurality of thin film transistors in the test unit, each of which includes an active layer, a gate electrode, a source electrode and a drain electrode, and the plurality of thin film transistors are used as test switching transistors.

For example, FIG. 41 is a schematic diagram of the plane structure of the active layer in FIG. 40. As illustrated by FIG. 41, the material of the active layer 123 is polysilicon. In FIG. 41, the structure of 12 complete active layers is shown, and each rectangular dotted box shows a complete active layer 123, that is, the 12 complete active layers 123 correspond to two repeating units. The six active layers 123 arranged in the first row are active layers of the test switching transistors corresponding to three blue sub pixels and three red sub pixels arranged in the first row, and the six active layers arranged in the second row are active layers of the test switching transistors corresponding to three blue sub pixels and three red sub pixels arranged in the second row, and only the six active layers 123 in the first row are described as a repeating unit.

For example, FIG. 42 is a schematic plan view of the first metal layer in FIG. 40. As illustrated by FIG. 42, the first metal layer 115 includes a first part 115A connected with the first color sub pixel and a second part 115B used as the gate electrode of the test switching transistor. The first color sub pixel 112A and the second color sub pixel 112B are not shown in FIG. 40 and FIG. 42, but they can be referred to 112A and 112B in FIG. 40. The second color sub pixel 112B includes a blue sub pixel B and a red sub pixel R. In the test stage, the test switching transistor is mainly used to control the blue sub pixel B and the red sub pixel R not to be turned on at the same time, even if only one of the blue sub pixel B and the red sub pixel R is turned on and the other is turned off at different times, so as to avoid the phenomenon of color deviation due to the low purity of the emitted light.

It should be noted that, the first part 115A in FIG. 42 is also the first signal transmission line 129 in FIG. 40.

For example, in combination with FIG. 40 and FIG. 42, the second part 115B of the first metal layer 115 includes a main body 115B1 and a branch part 115B2. The main body 115B1 is used to connect a first conductive layer first sub-part 118C of the first conductive layer 118, and the branch part 115B2 is used as a gate electrode of the test switching transistor, the first conductive layer first sub-part 118C provides a gate signal voltage for the test switching transistor. When describing the first conductive layer 118, the structure in the first conductive layer 118 will be described in detail.

For example, in combination with FIG. 40 and FIG. 42, the arrangement order of the sub pixels connected with the first signal transmission line 129 and the second signal transmission line 130 located in the first row is red sub pixel R, green sub pixel G, blue sub pixel B, green sub pixel G, blue sub pixel B, green sub pixel G, red sub pixel R, green sub pixel G, red sub pixel R, green sub pixel G, blue sub pixel B, and green sub pixel G. The arrangement order of the sub pixels connected with the first signal transmission line 129 and the second signal transmission line 130 located in the first row is the same as the arrangement order of the sub pixels connected with the first signal transmission lines 129 and the second signal transmission lines 130 in other regions of the fanout region 104 except the connection region 114 in FIG. 30.

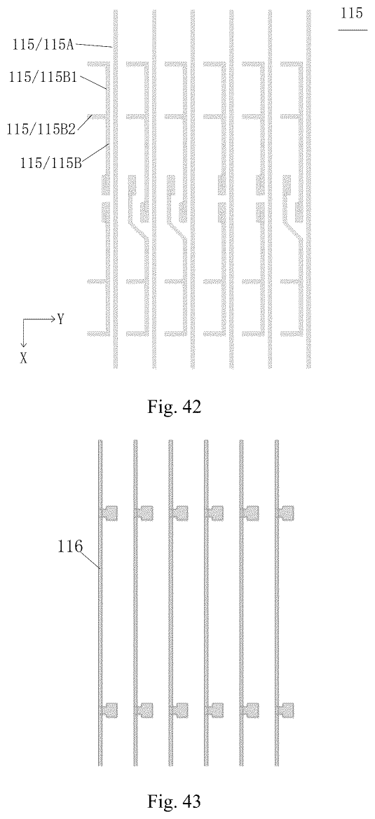

For example, FIG. 43 is a schematic diagram of the plane structure of the second metal layer in FIG. 40. As illustrated by combination with FIG. 40 and FIG. 43, the transistor finally transmits signals to the second metal layer 116, so that the first signal transmission line 129 connected with the first color sub pixel 112A and the second signal transmission line 130 connected with the second color sub pixel 112B are located in different metal layers, thereby controlling the lighting status of the first color sub pixel 112A and the second color sub pixel 112B, respectively.

It should be noted that, the second signal transmission line 130 in FIG. 40 is located on the second metal layer 116 shown in FIG. 43, and the strip shown in FIG. 43 corresponds to the second signal transmission line 130 in FIG. 40.

It should be noted that, although the blue sub pixel B in the first row and the red sub pixel R in the second row are connected with the same second signal transmission line 130, or although the red sub pixel B in the first row and the blue sub pixel B in the second row are connected with the same second signal transmission line 130, the problem of signal crosstalk will not occur due to the control of the test switching transistor.

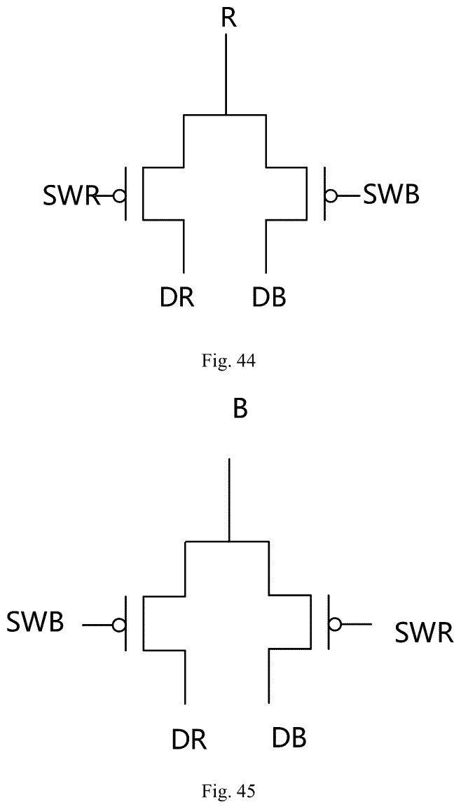

For example, FIG. 44 is a circuit diagram when the first test switching transistor corresponding to the red sub pixel in FIG. 40 is turned on, and FIG. 45 is a circuit diagram when the second test switching transistor corresponding to the blue sub pixel in FIG. 40 is turned on. As illustrated by FIG. 44 and FIG. 45, when testing the red monochrome picture, it is required that the red sub pixel is lit and the blue sub pixel is not lit; similarly, when testing a blue monochrome picture, it is required that the blue sub pixel is lit and the red sub pixel is not lit. For example, in one example, the input signal voltages are as follows: red sub pixel switching signal (SWR): −7V, blue sub pixel switching signal (SWB): +7V, red sub pixel source signal (DR): 3V, and blue sub pixel source signal (DB): 7V. For the first test switching transistor corresponding to the red sub pixel, when the SWR signal of −7V is applied to it, the first test switching transistor corresponding to the red sub pixel is turned on, and the DR signal of 3V is input into the second signal transmission line; at this time, when the applied SWB voltage is +7V, the second test switching transistor corresponding to the blue sub pixel is turned off, and the DB signal cannot be input to the second signal transmission line, so the voltage on the second signal transmission line is 3V, and the red sub pixel is lit at this time. For example, in another example, for the blue sub pixel, the second test switching transistor of the blue sub pixel is turned on when the SWB signal of −7V is applied to the second test switching transistor corresponding to the blue sub pixel, and the DB signal of 7V is input to the second signal transmission line; at this time, when the SWR voltage is +7V, the first test switching transistor corresponding to the red sub pixel is turned off, and the DR signal cannot be input to the second signal transmission line, so that the voltage on the second signal transmission line is 7V, and the corresponding blue sub pixel is lit.

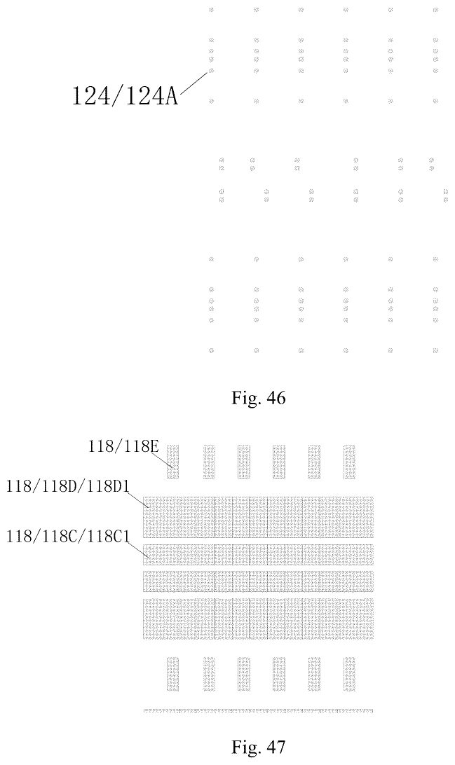

For example, FIG. 46 is a schematic plan view of an interlayer insulating layer in FIG. 31, which is arranged at a side of a second metal layer away from an active layer, as illustrated by FIG. 46, there are a plurality of third via hole structures 124A in the interlayer insulating layer 124, the first conductive layer and other structures at a side of the second metal layer 116 away from the active layer can be electrically connected with the first metal layer 115, the second metal layer 116 and the active layer through the plurality of third via hole structures 124A.

For example, FIG. 47 is a schematic plan view of the first conductive layer in FIG. 31. As illustrated by combination with FIG. 31, FIG. 42 and FIG. 47, the first conductive layer 118 includes a first conductive layer first sub-part 118C1, a first conductive layer second sub-part 118D1 and a first conductive layer third sub-part 118E. The first conductive layer first sub-part 118C1 is electrically connected with a main body 115B1 included in a second part 115b of the first metal layer 115 to provide a gate driving signal for the test switching transistor. The source electrode S1 of the first test switching transistor controlling the red sub pixel R is electrically connected with the first conductive layer second sub-part 118D1, thereby providing a monochromatic power supply voltage test signal for the red sub pixel R. The drain electrode D1 of the first test switching transistor for controlling the red sub pixel R is electrically connected with the second signal transmission line 130, and the source electrode SI and the drain electrode D1 are overlapped on two sides of the active layer of the first test switching transistor corresponding to the red sub pixel, and the second part 115B of the first metal layer 115 includes a branch part 115B2 serving as the gate electrode of the first test switching transistor for controlling the red sub pixel R. The first conductive layer third sub-part 118E is configured to be electrically connected with the second signal transmission line 130.

For example, as illustrated by FIG. 31, FIG. 42 and FIG. 47, the first conductive layer 118 further includes a first conductive layer first sub-part 118C2 and a first conductive layer sub-part 118D2. The first conductive layer first sub-part 118C2 is electrically connected with the main body 115B1 included in the second part 115b of the first metal layer 115 to provide a gate driving signal for the test switching transistor. The source electrode S1 of the second test switching transistor controlling the blue sub pixel B is electrically connected with the first conductive layer second sub-part 118D2, thereby providing a monochromatic power supply voltage test signal for the blue sub pixel B. The drain electrode D1 of the second test switching transistor for controlling the blue sub pixel B is electrically connected with the second signal transmission line 130, and the source electrode S1 and the drain electrode D1 are overlapped on two sides of the active layer of the second test switching transistor corresponding to the blue sub pixel, and the second part 115B of the first metal layer 115 includes a branch part 112b2 serving as the gate electrode of the second test switching transistor for controlling the blue sub pixel.

For example, in combination with FIG. 31, FIG. 42 and FIG. 47, in a repeating unit, the first conductive layer 118 includes two parallel first conductive layer first sub-parts 118C. For example, the first conductive layer first sub-part 118C on the upper side is connected with the gate electrode of the first test switching transistor that controls the red sub pixel to be lit, and the first conductive layer first sub-part 118C on the lower side is connected with the gate electrode of the second test switching transistor that controls the blue sub pixel to be lit, so that the gate driving voltage can be applied to the first test switching transistor that controls the red sub pixel to be lit and the second test switching transistor that controls the blue sub pixel to be lit respectively, so that the blue sub pixel and the red sub pixel are lit in different stages, so as to avoid color mixing of the red light and blue light.

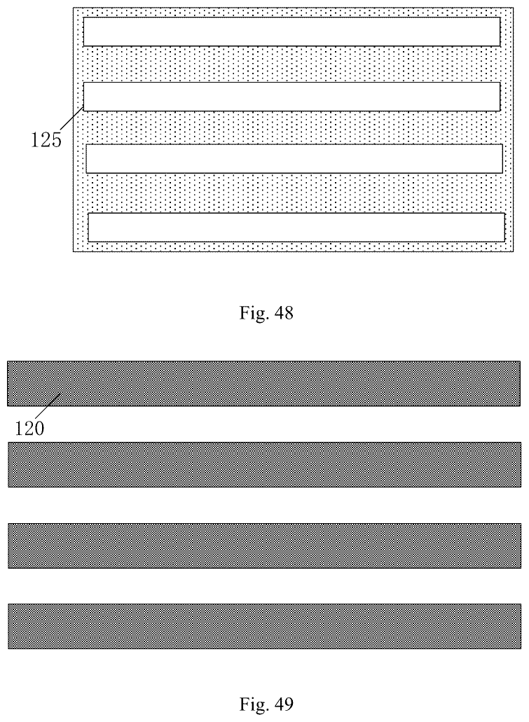

For example, FIG. 48 is a schematic plan view of the third planarization layer in FIG. 31. Combining with FIG. 31, FIG. 42 and FIG. 48, the third planarization layer 125 is provided with a plurality of grooves which can realize the electrical connection between the first conductive layer 118 and the second conductive layer 120 above the first conductive layer 118.

For example, FIG. 49 is a schematic diagram of the plane structure of the second conductive layer in FIG. 31. Combining with FIG. 31 and FIG. 49, the planar shape of the second conductive layer 120 is the same as the shape of the first conductive layer second sub-part 118D of the first conductive layer 118, and an orthographic projection of the second conductive layer 120 on the base substrate 111 overlaps with an orthographic projection of the first conductive layer second sub-part 118D of the first conductive layer 118 on the base substrate 111.

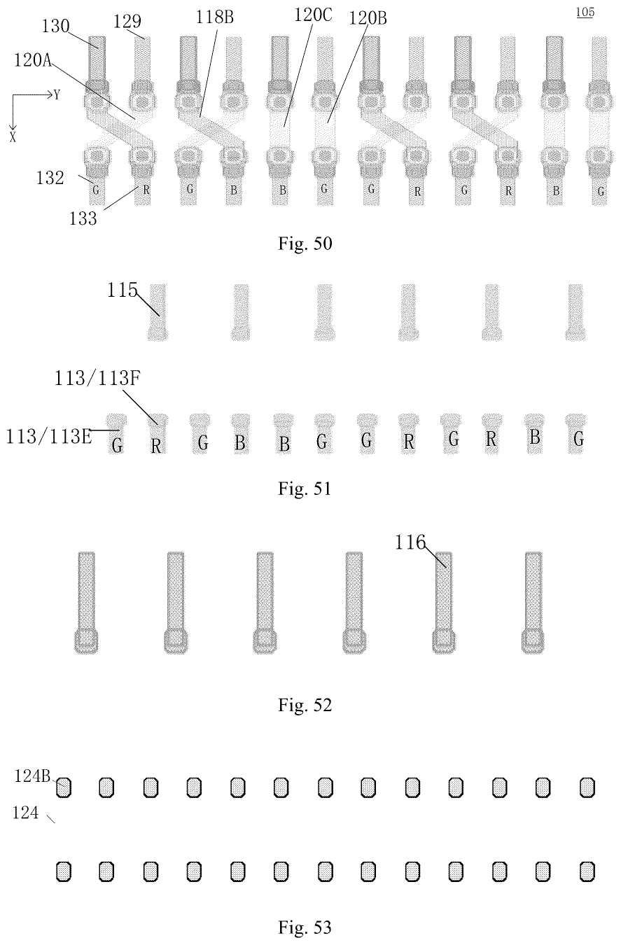

For example, FIG. 50 is a schematic diagram of the plane structure at the junction of the pad region and the test unit in a display substrate provided by at least one embodiment of the present disclosure. As illustrated by FIG. 50, in the pad region 105, a plurality of third signal transmission lines 132 connected with first color sub pixels and a plurality of fourth signal transmission lines 133 connected with second color sub pixel are arranged in sequence in the second direction Y. The first color sub pixel is a green sub pixel G and the second color sub pixel includes a blue sub pixel B or a red sub pixel R. In the pad region 105, a plurality of third signal transmission lines 132 and a plurality of fourth signal transmission lines 133 are arranged in the second direction Y. The arrangement order of the sub pixels connected with the plurality of third signal transmission lines 132 and the plurality of fourth signal transmission lines 133 is the same as the arrangement order of the sub pixels connected with the plurality of data lines 113 and the plurality of data connection lines 128, and a part of the plurality of third signal transmission lines 132 are in odd-numbered columns, the other part of the plurality of third signal transmission lines 132 are in even-numbered columns, a part of the plurality of fourth signal transmission lines 133 are in odd-numbered columns, and the other part of the plurality of fourth signal transmission lines 133 are in an even-numbered column.

For example, in FIG. 50, the sub pixels connected with the plurality of third signal transmission lines 132 and the plurality of fourth signal transmission lines 133 are green sub pixel G, red sub pixel R, green sub pixel G, blue sub pixel B, blue sub pixel B, green sub pixel G, green sub pixel G, red sub pixel R, green sub pixel G, red sub pixel R, blue sub pixel B and green sub pixel G in order, so as to be the same as the arrangement order of the data lines 113 and the data connection lines 128 at the junction of the display region 101 and the fanout region 104 in FIG. 30.

For example, FIG. 51 is a schematic diagram of the plane structure of the first metal layer in FIG. 50. As illustrated by FIG. 51, the first metal layer 115 includes a plurality of mutually spaced parts in a first row, and the plurality of parts in the first row correspond to the first signal transmission lines 129 connected with the first color sub pixels in the test unit. A plurality of parts in the second row correspond to the third signal transmission lines 132 connected with the first color sub pixels and the fourth signal transmission lines 133 connected with the second color sub pixels in the pad region 105, that is, the third signal transmission lines 132 connected with the first color sub pixels and the fourth signal transmission lines 133 connected with the second color sub pixels in the pad region 105 are arranged in the same layer. In FIG. 51, the third signal transmission line 132 and the fourth signal transmission line 133 from left to right receive the driving signals of the green sub pixel G, the red sub pixel R, the green sub pixel G, the blue sub pixel B, the blue sub pixel B, the green sub pixel G, the green sub pixel G, the red sub pixel R, the green sub pixel G, the red sub pixel R, the blue sub pixel B and the green sub pixel G in order to drive the corresponding color sub pixel to be lit.

For example, FIG. 52 is a schematic diagram of the plane structure of the second metal layer in FIG. 50. As illustrated by combination with FIG. 50 and FIG. 52, the second metal layer 116 includes a plurality of mutually spaced parts, and the mutually spaced parts included in the second metal layer 116 are respectively inserted at the spaced positions of the mutually spaced parts included in the first metal layer 115 in FIG. 51.

For example, FIG. 53 is a schematic diagram of the position of the fourth via hole structure of the interlayer insulating layer at a side of the second metal layer away from the active layer in FIG. 50. As illustrated by FIG. 53, a plurality of fourth via hole structures 124B are arranged in the interlayer insulating layer 124, and the first conductive layer or other layer structures arranged in the second metal layer 116 can be electrically connected with the first metal layer 115 and the second metal layer 116 through the plurality of fourth via hole structures 124B.

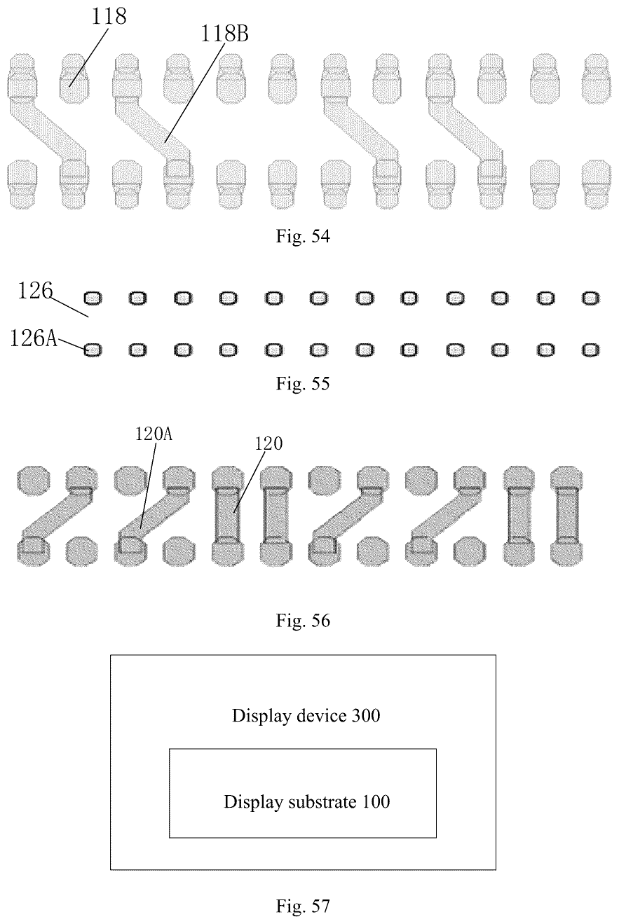

For example, FIG. 54 is a schematic plan view of the first conductive layer in FIG. 50. As illustrated by FIG. 54, the first conductive layer 118 includes a first transfer line 118B extending from the upper left corner to the lower right corner.

For example, FIG. 55 is a schematic plan view of the fourth planarization layer in FIG. 50. As illustrated by FIG. 55, the fourth planarization layer 126 is provided with a plurality of fifth via hole structures 126A, which are used to connect the first conductive layer 118 with other conductive layer structures thereon.

For example, FIG. 56 is a schematic plan view of the second conductive layer in FIG. 50. As illustrated by FIG. 56, the second conductive layer 120 includes a second transfer line 120A extending from the upper right corner to the lower left corner.

For example, in combination with FIG. 50, FIG. 54 and FIG. 56, the at least one third signal transmission line 132 arranged in an odd-numbered column and a fourth signal transmission line 133 arranged in an even-numbered column are arranged adjacent to each other, and on a plane parallel to the main surface of the base substrate 111, the second transfer line 120A connected with the at least one third signal transmission line 132 arranged in the odd-numbered column crosses with the first transfer line 118B connected with the fourth signal transmission line 133 arranged in an even-numbered column. The third signal transmission line 132 arranged in odd-numbered column is electrically connected with a corresponding first signal transmission lines 129 through a second transfer line 120A, and the fourth signal transmission line 133 arranged in even-numbered column is electrically connected with a corresponding second signal transmission lines 130 through a first transfer line 118B, the first transfer line 118 and the second transfer line 120A are located in different layers, the first transfer line 118B is in the first conductive layer 118 and the second transfer line 120A is in the second conductive layer.

For example, in combination with FIG. 50, FIG. 54 and FIG. 56, the third signal transmission line 132 and the first signal transmission line 129 arranged in the even-numbered columns are electrically connected through a third transfer line 120B, and the fourth signal transmission line 133 and the second signal transmission line 130 arranged in the odd-numbered columns are electrically connected through a fourth transfer line 120C, both the third transfer line 120B and the fourth transfer line 120C are arranged in the second conductive layer 120.

For example, in combination with FIG. 50, FIG. 54 and FIG. 56, at least one third signal transmission line 132 arranged in the even-numbered column and one fourth signal transmission line 133 arranged in the odd-numbered column are arranged adjacent to each other, and on a plane parallel to the main surface of the base substrate 111, a third transfer line 120B connected with at least one third signal transmission line 132 arranged in an even-numbered column and a fourth transfer line 120C connected with one fourth signal transmission line 133 arranged in the odd-numbered column do not cross with each other.

For example, as illustrated by FIG. 31, the connection electrode 131E extends in the direction from at least one data connection line to a data line adjacent thereto at a junction of the display region and the fanout region.

For example, the above can also take 16 sub pixels arranged in the second direction Y as a cycle, or take 16 sub pixels arranged in the second direction Y as a cycle, which is not limited by the embodiment of the present disclosure.

At least one embodiment of the present disclosure further provides a display device. FIG. 57 is a schematic diagram of a display device provided by an embodiment of the present disclosure. As illustrated by FIG. 57, the display device 300 includes any one of the above-mentioned display substrates 100. Therefore, the display device 300 can avoid the phenomenon that the parasitic capacitances of data signal lines connected with the sub pixels of the same color are different when they are in different film layers, and further can avoid the problem that the data signal writing amount is different due to the different loads of data signal lines connected with the sub pixels of the same color, that is, the influence caused by different parasitic capacitances can be avoided, and the subsequent connection order of data signal lines in the driving circuit will not be affected.

For example, in some examples, the display device may further include a functional part located at a side of the base substrate away from the light emitting element. For example, the functional component includes at least one of a camera module (for example, a front camera module), a 3D structured light module (for example, a 3D structured light sensor), a time-of-flight 3D imaging module (for example, a time-of-flight sensor), an infrared sensing module (for example, an infrared sensing sensor), and the like. The display device can also be a smart phone, a tablet computer, a television, a monitor, a notebook computer, a digital photo frame, a navigator and other products or components with display functions.

The display substrate and the display device provided by at least one embodiment of the present disclosure have at least one of the following beneficial technical effects:

(1) In the display substrate provided by at least one embodiment of the present disclosure, by performing a jumper design on data lines or a jumper design on data lines and data connection line at the connection region of the fanout region adjacent to the display region (AA), the arrangement order of sub pixels connected with the data lines and the data connection lines at the position of the display region close to the fanout region is different from the arrangement order of sub pixels connected with the plurality of first signal transmission lines and the plurality of second signal transmission lines at the position of the wiring region and fanout region away from the display region, so that the first signal transmission lines or the second signal transmission lines connected with the sub pixels of the same color in the fanout region are adjusted to be located in the same film layer, so as to avoid the difference in parasitic capacitance caused by different film layers of the first signal transmission lines or the second signal transmission lines connected with the sub pixels of the same color, and further avoid the problem that different loads of the signal transmission lines connected with sub pixels of the same color cause different data signal writing amounts.

(2) In the display substrate provided by at least one embodiment of the present disclosure, the third data line is wound to the connection pad from the position close to the wiring region in the display region through the third conductive layer, and the fourth data line is connected with the connection pad from the position away from the wiring region in the display region through the third conductive layer, that is, the third data line crosses the first signal transmission line connected with the fourth data line, but the fourth data line does not cross the second signal transmission line connected with the third data line. Because only the third data line located in the third conductive layer and connected with the blue sub pixel overlaps with the first signal transmission line connected with the green sub pixel, but there is no overlap between the fourth data line connected with the green sub pixel and the second signal transmission line connected with the blue sub pixel, the parasitic capacitance can be reduced, so that the capacitance difference between the film layers of different signals brought by jumpers can be minimized.

(3) In the display substrate provided by at least one embodiment of the present disclosure, in a repeating unit, the first conductive layer includes two parallel first conductive layer first sub-parts, the first conductive layer first sub-parts located on the upper side are all connected with the gate electrode of the first test switching transistor that controls the red sub pixel to be lit, and the first conductive layer first sub-parts located on the lower side are all connected with the gate electrode of the second test switching transistor that controls the blue sub pixel to be lit. In this way, the gate driving voltage can be applied to the first test switching transistor that controls the red sub pixel to be lit and the second test switching transistor that controls the blue sub pixel to be lit respectively, so that the blue sub pixel and the red sub pixel are lit at different stages, thus not causing the mixed color of red light and blue light.

The following points need to be explained:

(1) The drawings of the embodiment of this disclosure only relate to the structure related to the embodiment of this disclosure, and other structures can refer to the general design.

(2) For the sake of clarity, in the drawings used to describe the embodiments of the present disclosure, the thickness of layers or regions is enlarged or reduced, that is, these drawings are not drawn to actual scale.

(3) In the case of no conflict, the embodiments of the present disclosure and the features in the embodiments can be combined with each other to obtain a new embodiment.

The above is only the specific implementation of this disclosure, but the protection scope of this disclosure is not limited thereto, and the protection scope of this disclosure shall be subject to the protection scope of the claims.

1. A display substrate, comprising:
a base substrate, comprising a display region and a peripheral region surrounding the display region, the peripheral region comprising a fanout region adjacent to the display region and a pad region at a side of the fanout region away from the display region; and
a plurality of sub pixels arranged in a matrix and arranged in the display region, each column of the plurality of sub pixels being connected with a data line; the fanout region comprising a connection region adjacent to the display region, a part of data lines being directly connected with connection pads located in the connection region, and other part of the data lines being connected with connection pads located in the connection region through data connection lines;
wherein the plurality of sub pixels comprise a plurality of columns of first color sub pixels and a plurality of columns of second color sub pixels, and the connection pads comprise a plurality of first connection pads and a plurality of second connection pads, the plurality of first connection pads are electrically connected with the plurality of columns of first color sub pixels and the plurality of second connection pads are electrically connected with the plurality of columns of second color sub pixels;
a plurality of first signal transmission lines and a plurality of second signal transmission lines are arranged at intervals in positions of the fanout region close to the pad region, the plurality of first signal transmission lines are arranged in a first metal layer, and the plurality of second signal transmission lines are arranged in a second metal layer which is different from the first metal layer;
the plurality of first signal transmission lines and the plurality of first connection pads are electrically connected in one-to-one correspondence, and the plurality of second signal transmission lines and the plurality of second connection pads are electrically connected in one-to-one correspondence;
two adjacent data connection lines of the data connection lines and at least two data lines of the data lines which are located between the two adjacent data connection lines are taken as a data line group,
connection pads connected with the at least two data lines in one data line group at least comprise one first connection pad and one second connection pad, in at least one data line group, an orthographic projection of a data line connected with the second connection pad on the base substrate and an orthographic projection of a first signal transmission line connected with the first connection pad on the base substrate have an overlapping part in the fanout region; or, connection pads respectively connected with the at least two data lines and the two adjacent data connection lines in the data line group comprise a first connection pad and a second connection pad, and in at least one data line group, one data connection line of the two adjacent data connection lines is electrically connected with the first connection pad or the second connection pad through a connection electrode, and an orthographic projection of the connection electrode on the base substrate and an orthographic projection of a data line, which is adjacent to the data connection line connected with the connection electrode, on the base substrate has an overlapping part in the fanout region.

2. The display substrate according to claim 1, wherein,
the data lines and the data connection lines are arranged in a third conductive layer, and connection pads connected with two adjacent data lines in one data line group are the first connection pad and the second connection pad respectively;
a first data line located in an odd-numbered column among the two adjacent data lines in one data line group crosses a first signal transmission line connected with a second data line located in an even-numbered column and being adjacent to the first data line;
the second data line located in the even-numbered column extends to a side of a junction of the display region and the fanout region close to the first data line adjacent to the second data line, so as to be electrically connected with a corresponding first signal transmission line of the plurality of first signal transmission lines.

3. The display substrate according to claim 2, wherein,
the first data line located in the odd-numbered column first extends to a side close to the pad region in the fanout region, and then extends to the second data line located in the even-numbered column and being adjacent to the first data line, so as to form an L-shaped structure or an inverted L-shaped structure, and the second data line located in the even-numbered column first extends to a side close to the first data line in the fanout region, and then extends to a side close to the pad region to form an unclosed quadrilateral with the first data line.

4. The display substrate according to claim 2, wherein,
on a plane parallel to a main surface of the base substrate, the first data line and the first signal transmission line connected with the second data line cross with each other; the second data line and the second signal transmission line electrically connected with the first data line do not cross with each other.

5. The display substrate according to claim 2, wherein the plurality of first signal transmission lines and the plurality of second signal transmission lines are alternately arranged in sequence.

6. The display substrate according to claim 5, wherein,
a plurality of third signal transmission lines and a plurality of fourth signal transmission lines are arranged in the second direction and in the pad region, an arrangement order of the sub pixels connected with the plurality of third signal transmission lines and the plurality of fourth signal transmission lines is consistent with an arrangement order of the sub pixels connected with the data lines and the data connection lines, a part of the plurality of third signal transmission lines are in odd-numbered columns, other part of the plurality of third signal transmission lines are in even-numbered columns, a part of the plurality of fourth signal transmission lines are in odd-numbered columns, and other part of the plurality of fourth signal transmission lines are in even-numbered columns, and at least one of the plurality of third signal transmission lines and the second data line correspond to the sub pixels with a same color, and at least one of the plurality of fourth signal transmission lines and the first data line corresponds to the sub pixels with a same color.

7. The display substrate according to claim 6, wherein,
a third signal transmission line arranged in an even-numbered column is electrically connected with a corresponding first signal transmission line through a first transfer line, and a fourth signal transmission line arranged in an odd-numbered column is electrically connected with a corresponding second signal transmission line through a second transfer line, the first transfer line and the second transfer line are arranged in different layers, the first transfer line is arranged in a first conductive layer, the second transfer line is arranged in a second conductive layer, and the first conductive layer and the second conductive layer are different layers.

8. The display substrate according to claim 7, wherein,
a fourth signal transmission line arranged in an even-numbered column is electrically connected with a corresponding second signal transmission line through a fourth transfer line, and a third signal transmission line arranged in an odd-numbered column is electrically connected with a corresponding first signal transmission line through a third transfer line, and both the third transfer line and the fourth transfer line are arranged in the second conductive layer.

9. The display substrate according to claim 7, wherein,
at least one third signal transmission line arranged in the even-numbered column and one fourth signal transmission line arranged in the odd-numbered column are arranged adjacent to each other, and, on a plane parallel to a main surface of the base substrate, the first transfer line connected with the at least one third signal transmission line arranged in the even-numbered column and the second transfer line connected with the fourth signal transmission line arranged in the odd-numbered column cross with each other.

10. The display substrate according to claim 1, wherein,
the data lines and the data connection lines are arranged in a third conductive layer,
at least one data connection line located in an odd-numbered column and one data line located in an even-numbered column are arranged adjacent to each other;
the at least one data connection line located in the odd-numbered column crosses the data line located in the even-numbered column which is adjacent to the at least one data connection line through a first connection electrode, so as to be electrically connected with a first signal transmission line corresponding to the at least one data connection line located in the odd-numbered column, the first connection electrode is located in a second conductive layer, and the second conductive layer and the third conductive layer are different layers;
the data line located in the even-numbered column is electrically connected with a corresponding second signal transmission line.

11. The display substrate according to claim 10, wherein the first connection electrode extends in a direction from the at least one data connection line located in the odd-numbered column to the data line located in the even-numbered column at a junction of the display region and the fanout region.

12. The display substrate according to claim 1, wherein,
the data lines and the data connection lines are arranged in a third conductive layer,
at least one data line located in an odd-numbered column and one data connection line located in an even-numbered column are arranged adjacent to each other;
the data connection line located in the even-numbered column crosses the data line located in the odd-numbered column through a second connection electrode, so as to be electrically connected with a second signal transmission line corresponding to the data connection line located in the even-numbered column, the second connection electrode is located in a second conductive layer, and the second conductive layer and the third conductive layer are different layers;
the at least one data line located in the odd-numbered column is electrically connected with a corresponding first signal transmission line.

13. The display substrate according to claim 12, wherein the second connection electrode extends in a direction from the data connection line located in the even-numbered column to the at least one data line located in the odd-numbered column at a junction of the display region and the fanout region.

14. The display substrate according to claim 10, wherein the plurality of first signal transmission lines are located in even-numbered columns and the plurality of second signal transmission lines are located in odd-numbered columns.

15. The display substrate according to claim 10, wherein,
a plurality of third signal transmission lines and a plurality of fourth signal transmission lines are arranged at a junction of the fanout region and the pad region in the second direction, an arrangement order of the sub pixels connected with the plurality of third signal transmission lines and the plurality of fourth signal transmission lines is consistent with an arrangement order of the sub pixels connected with the data lines and the data connection lines, and a part of the plurality of third signal transmission lines is in odd-numbered columns, other part of the plurality of third signal transmission lines is in even-numbered columns, a part of the plurality of fourth signal transmission lines is in the odd-numbered columns, other part of the plurality of fourth signal transmission lines is in the even-numbered columns, and the plurality of third signal transmission lines and the first connection pads are arranged in one-to-one correspondence, and correspond to the sub pixels of a same color, and the plurality of fourth signal transmission lines and the second connection pads are arranged in one-to-one correspondence, and correspond to the sub pixels of a same color.

16. The display substrate according to claim 15, wherein,
the third signal transmission line arranged in the odd-numbered column is electrically connected with a corresponding first signal transmission line through a first transfer line, and a fourth signal transmission line arranged in the even-numbered column is electrically connected with a corresponding second signal transmission line through a second transfer line, the first transfer line is in a second conductive layer, the second transfer line is in a first conductive layer, and the first conductive layer and the second conductive layer are different layers.

17. The display substrate according to claim 16, wherein,
the third signal transmission line arranged in the even-numbered column is electrically connected with a corresponding first signal transmission line through a third transfer line, and the fourth signal transmission line arranged in the odd-numbered column is electrically connected with a corresponding second signal transmission line through a fourth transfer line, and both the third transfer line and the fourth transfer line are arranged in the second conductive layer.

18. The display substrate according to claim 17, wherein,
at least one of the third signal transmission lines arranged in the odd-numbered column and one fourth signal transmission line arranged in the even-numbered column are arranged adjacent to each other, and on a plane parallel to a main surface of the base substrate, the first transfer line connected with the at least one of the third signal transmission lines arranged in the odd-numbered column and the second transfer line connected with the fourth signal transmission line arranged in the even-numbered column cross with each other.

19. The display substrate according to claim 1, wherein the fanout region further comprises a semiconductor layer, a first gate layer, a second gate layer, an interlayer insulating layer, a first conductive layer, a planarization layer and a second conductive layer which are sequentially stacked;
the first color sub pixels comprise a green sub pixel, and the second color sub pixels comprise a red sub pixel and a blue sub pixel;
a test unit is arranged in the fanout region, and the test unit comprises a first test switching transistor connected with the red sub pixel and a second test switching transistor connected with the blue sub pixel;
a source electrode of the first test switching transistor is connected with a first test signal input end, a part of the plurality of second signal transmission lines is electrically connected with a drain electrode of the first test switching transistor, and a gate electrode of the first test switching transistor is electrically connected with a first part of the first conductive layer;
a source electrode of the second test switching transistor is connected with a second test signal input end, other part of the plurality of second signal transmission lines is electrically connected with a drain electrode of the second test switching transistor, and a gate electrode of the second test switching transistor is electrically connected with a second part of the first conductive layer;
the first part and the second part of the first conductive layer are spaced apart from each other.

20. A display device, comprising the display substrate according to claim 1.
